(19) United States
(12) Patent Application Publication
(10) Pub. No.: US 2026/0362783 A1
(43) Pub. Date: Nov. 12, 2026

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Yi-Ruei JHAN, Keelung City (TW); Wei-Ting WANG, Taipei City (TW); Kuan-Ting PAN, Taipei City (TW); Shi-Ning JU, Hsinchu City (TW); Kuo-Cheng CHIANG, Zhubei City (TW); Chih-Hao WANG, Baoshan Township (TW)

(73) Assignee: Taiwan Semiconductor Manufacturing Company, Ltd., Hsinchu (TW)

(21) Appl. No.: 19/745,135

(22) Filed: Jul. 17, 2026

Related U.S. Application Data
(63) Continuation of application No. 19/024,739, filed on Jan. 16, 2025.
(60) Provisional application No. 63/712,706, filed on Oct. 28, 2024.

(51) Int. Cl. H10D 84/01; H10D 84/83

(52) U.S. Cl. CPC H10D 84/0153; H10D 84/8316; H10D 84/832

(57) ABSTRACT

Semiconductor structures and methods for manufacturing the same are provided. The semiconductor structure includes a plurality of first nanostructures formed over a substrate along a first direction, a plurality of second nanostructures formed adjacent to the first nanostructures. The semiconductor structure includes a first gate structure in a gate region formed on the first nanostructures along a second direction, and a first S/D structure in an S/D region adjacent to the first gate structure. The semiconductor structure includes a second gate structure formed on the second nanostructures. The semiconductor structure includes a dielectric wall structure formed along the first direction, and the dielectric wall structure has a first portion in the gate region and a second portion in the S/D region, and a bottom surface of the second portion is higher than a bottom surface of the first portion of the dielectric wall structure.

### CROSS REFERENCE TO RELATED APPLICATIONS

This application is a Continuation application of U.S. patent application Ser. No. 19/024,739, filed on Jan. 16, 2025, which claims the benefit of U.S. Provisional Application No. 63/712,706, filed on Oct. 28, 2024, the entirety of which are incorporated by reference herein.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, this miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). However, integration of fabrication of the multi-gate devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIGS. 1A to 1F illustrate perspective views of intermediate stages of manufacturing a semiconductor structure in accordance with some embodiments.

FIG. 2 shows a top-view representation of the semiconductor structure, in accordance with some embodiments.

FIGS. 3A-1 to FIGS. 3N-1 illustrate cross-sectional representations of various stages of manufacturing the semiconductor structure shown along line A-A’ in FIG. 1F and in FIG. 2, in accordance with some embodiments.

FIGS. 3A-2 to FIGS. 3N-2 illustrate cross-sectional representations of various stages of manufacturing the semiconductor structure shown along line B-B’ in FIG. 1F and in FIG. 2, in accordance with some embodiments.

FIGS. 3A-3 to FIGS. 3N-3 illustrate cross-sectional representations of various stages of manufacturing the semiconductor structure shown along line C-C’ in FIG. 1F and in FIG. 2, in accordance with some embodiments.

FIG. 4 shows a top-view representation of the semiconductor structure after forming the opening, in accordance with some embodiments.

FIG. 5 shows a top-view representation of the semiconductor structure after forming the first gate structure and the second gate structure, in accordance with some embodiments.

FIG. 6A shows a top-view representation of a semiconductor structure after forming the first gate structure and the second gate structure, in accordance with some embodiments.

FIG. 6B illustrates a cross-sectional representation of the semiconductor structure shown along line D-D’ in FIG. 6A, in accordance with some embodiments.

FIG. 7A shows a top-view representation of a semiconductor structure after forming the first gate structure and the second gate structure, in accordance with some embodiments.

FIG. 7B illustrates a cross-sectional representation of the semiconductor structure shown along line B-B’ and E-E’ in FIG. 7A, in accordance with some embodiments.

FIG. 8 illustrates a cross-sectional representation of a semiconductor structure, in accordance with some embodiments.

FIG. 9 illustrates a cross-sectional representation of a semiconductor structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The fins described below may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments of semiconductor structures and methods for forming the same are provided. The semiconductor structures may include first nanostructures and second nanostructures along a first direction (e.g. x-axis). A first gate structure is formed over the first nanostructures, and a second gate structure is formed over the second nanostructures. A dielectric wall structure is between the first gate structure and the second gate structure. A first S/D structure is adjacent to the first gate structure, and a second S/D structure is adjacent to the second gate structure. The dielectric wall structure extends from the gate region to the S/D region. The dielectric wall structure has a reversed T-shaped structure, therefore gate contact structure is formed on the first gate structure and is not in contact with the dielectric wall structure to have more landing window. In addition, the first gate structure is filled into the space between the dielectric wall structure and the nanostructures to further reduce capacitance. Therefore, the performance of the semiconductor structure is improved. The source/drain (S/D) structure or region(s) may refer to a source or a drain, individually or collectively dependent upon the context.

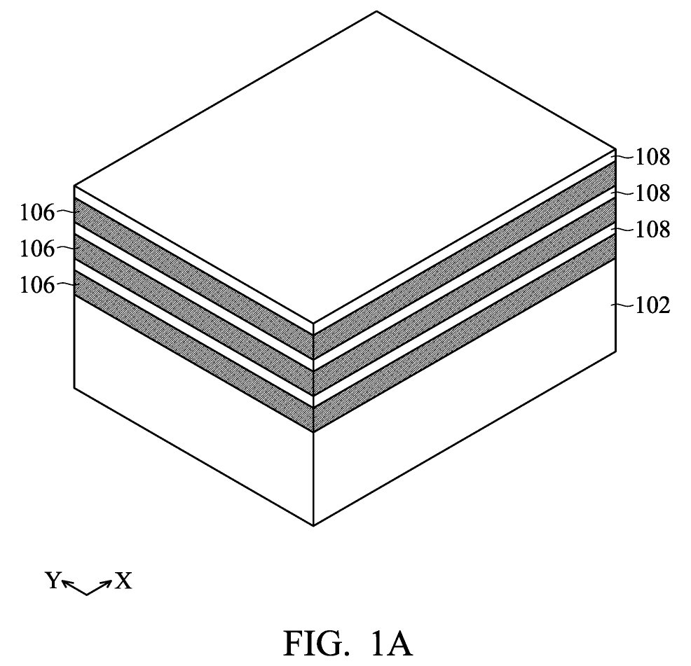

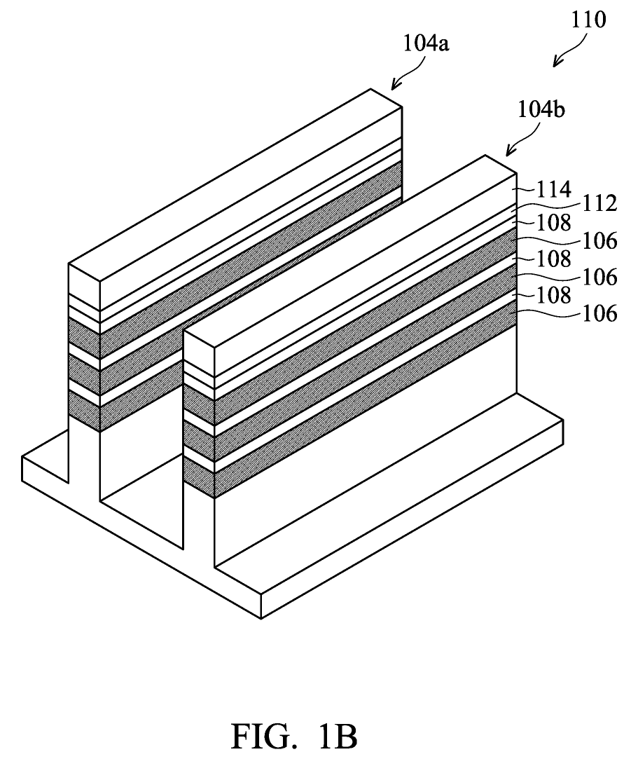

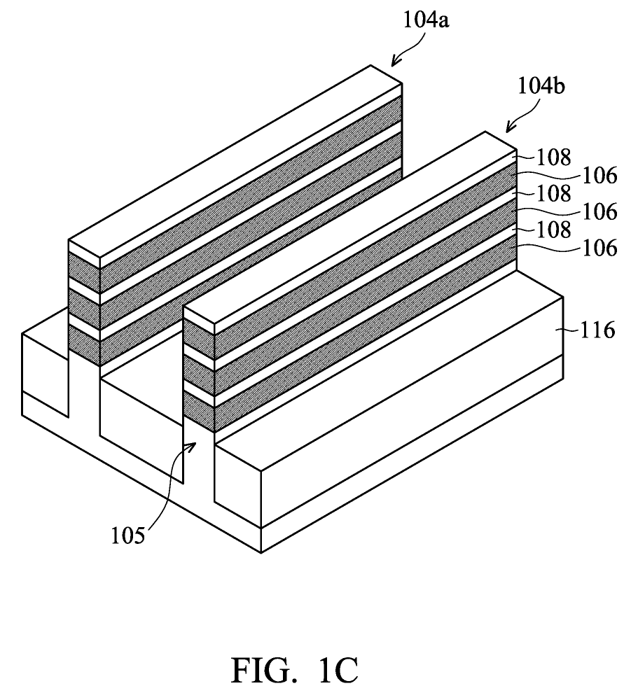

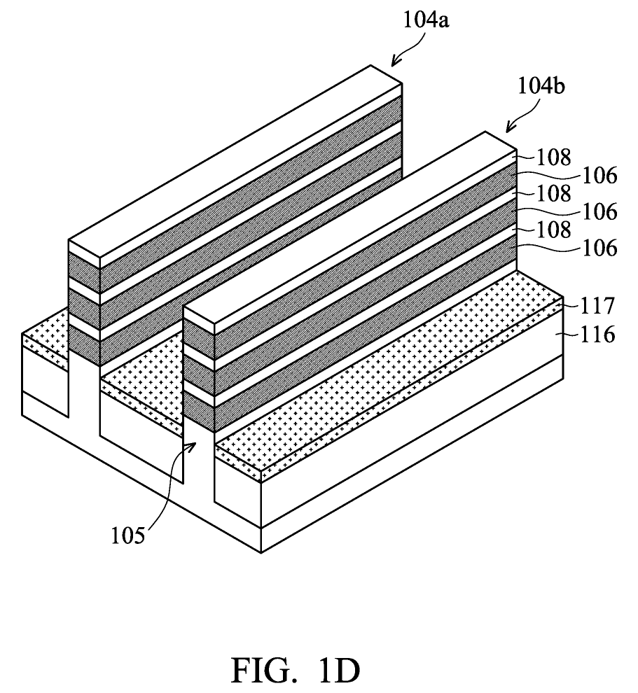

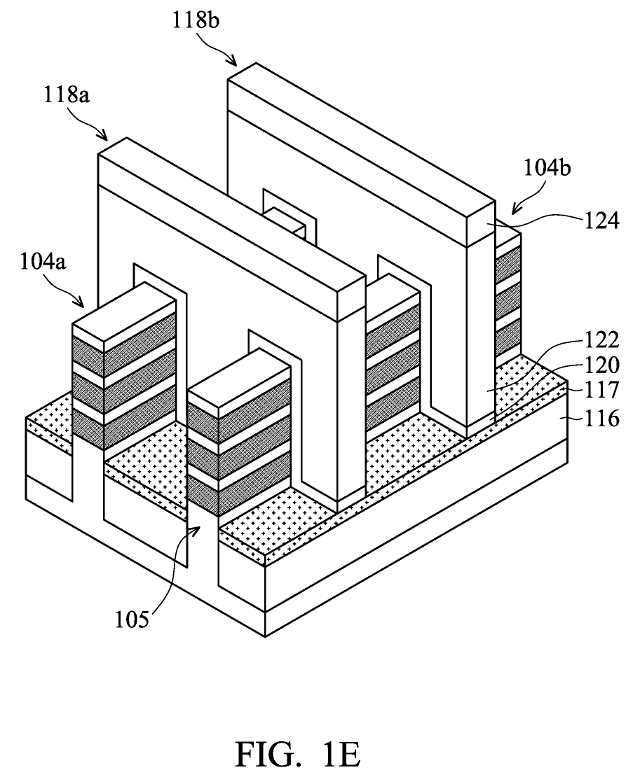

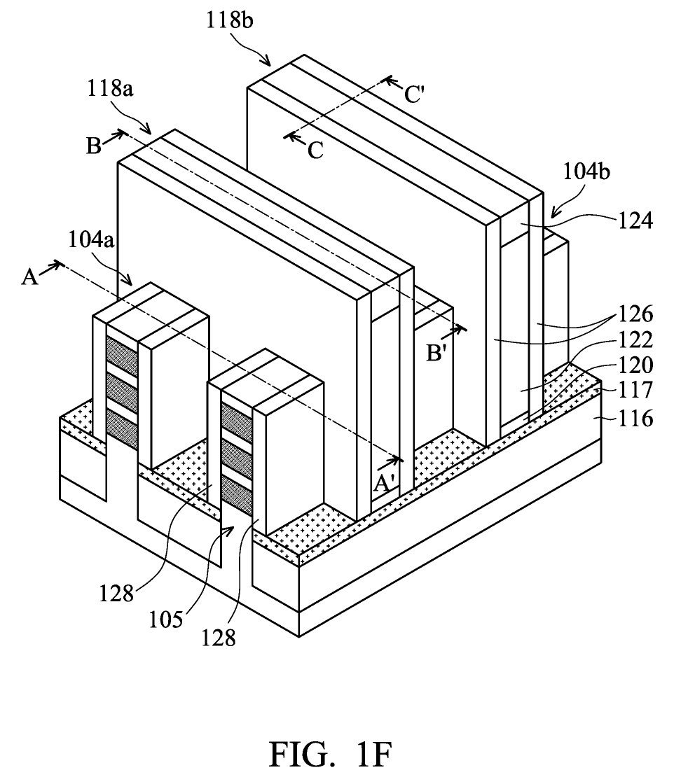

FIGS. 1A to 1F illustrate perspective views of intermediate stages of manufacturing a semiconductor structure 100a, in accordance with some embodiments. As shown in FIG. 1A, first semiconductor material layers 106 and second semiconductor material layers 108 are formed over a substrate 102.

The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102. In some embodiment, the first semiconductor material layers 106 and the second semiconductor material layers 108 are made of different semiconductor materials. In some embodiments, the first semiconductor material layers 106 are made of SiGe, and the second semiconductor material layers 108 are made of silicon. It should be noted that although three first semiconductor material layers 106 and three second semiconductor material layers 108 are formed, the semiconductor structure may include more or fewer first semiconductor material layers 106 and second semiconductor material layers 108. For example, the semiconductor structure may include two to five of the first semiconductor material layers 106 and the second semiconductor material layers 108.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

Afterwards, as shown in FIG. 1B, after the first semiconductor material layers 106 and the second semiconductor material layers 108 are formed as a semiconductor material stack over the substrate 102, the semiconductor material stack is patterned to form a first fin structure 104a and a second fin structure 104b, in accordance with some embodiments. In some embodiments, each of the first fin structure 104a and a second fin structure 104b includes a base fin structure 105 and the semiconductor material stack of the first semiconductor material layers 106 and the second semiconductor material layers 108.

In some embodiments, the patterning process includes forming a mask structure 110 over the semiconductor material stack, and etching the semiconductor material stack and the underlying substrate 102 through the mask structure 110. In some embodiments, the mask structure 110 is a multilayer structure including a pad oxide layer 112 and a nitride layer 114 formed over the pad oxide layer 112. The pad oxide layer 112 may be made of silicon oxide, which is formed by thermal oxidation or chemical vapor deposition (CVD), and the nitride layer 114 may be made of silicon nitride, which is formed by chemical vapor deposition (CVD), such as low-pressure chemical vapor deposition (LPCVD) or plasma-enhanced CVD (PECVD).

Next, as shown in FIG. 1C, after the first fin structure 104a and the second fin structure 104b is formed, an isolation structure 116 is formed around first fin structure 104a and the second fin structure 104b, and the mask structure 110 is removed, in accordance with some embodiments.

The isolation structure 116 is configured to electrically isolate active regions (e.g. the first fin structure 104a and the second fin structure 104b) of the semiconductor structure 100a and is also referred to as shallow trench isolation (STI) feature in accordance with some embodiments.

The isolation structure 116 may be formed by depositing an insulating layer over the substrate 102 and recessing the insulating layer so that the first fin structure 104a and the second fin structure 104b is protruded from the isolation structure 116. In some embodiments, the isolation structure 116 is made of silicon oxide, silicon nitride, silicon oxynitride (SiON), another suitable insulating material, or a combination thereof. In some embodiments, a dielectric liner (not shown) is formed before the isolation structure 116 is formed, and the dielectric liner is made of silicon nitride and the isolation structure formed over the dielectric liner is made of silicon oxide.

Afterwards, as shown in FIG. 1D, a mask layer 117 is formed on the isolation structure 116, in accordance with some embodiments. The mask layer 117 is used to as an etch stop layer when forming a trench from back-side of the substrate 102. In addition, the mask layer 117 is used as a protection layer to protect the isolation structure 116.

In some embodiments, the mask layer 117 is made of silicon nitride (SiN), silicon oxide (SiOx), silicon oxynitride (SiON), silicon carbon nitride (SiCN), silicon oxide carbonitride (SiOCN), Silicon oxycarbide (SiCO), silicon carbide (SiC), high-k dielectric material (HfO or AlOx), or another applicable material. In some embodiments, the mask layer 117 is formed by chemical vapor deposition (CVD), ALD, other application methods, or a combination thereof.

Afterwards, as shown in FIG. 1E, after the mask layer 117 is formed, first dummy gate structures 118a and second dummy gate structures 118b are formed across the first fin structure 104a and the second fin structure 104b and extend over the isolation structure 116, in accordance with some embodiments. The first dummy gate structures 118a and the second dummy gate structures 118b may be used to define the source/drain (S/D) regions and the channel regions of the resulting semiconductor structure 100a.

In some embodiments, each of the first dummy gate structures 118a and each of the second dummy gate structures 118b includes dummy gate dielectric layers 120 and dummy gate electrode layers 122. In some embodiments, the dummy gate dielectric layers 120 are made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layers 120 are formed using thermal oxidation, chemical vapor deposition (CVD), atomic vapor deposition (ALD), physical vapor deposition (PVD), another suitable method, or a combination thereof.

In some embodiments, the conductive material includes polycrystalline-silicon (poly-Si), poly-crystalline silicon-germanium (poly-SiGe), metallic nitrides, metallic silicides, metals, or a combination thereof. In some embodiments, the dummy gate electrode layers 122 are formed using chemical vapor deposition (CVD), physical vapor deposition (PVD), or a combination thereof.

In some embodiments, hard mask layers 124 are formed over the dummy gate structures 118. In some embodiments, the hard mask layers 124 include multiple layers, such as an oxide layer and a nitride layer. In some embodiments, the oxide layer is silicon oxide, and the nitride layer is silicon nitride.

The formation of the dummy gate structures 118 may include conformally forming a dielectric material as the dummy gate dielectric layers 120. Afterwards, a conductive material may be formed over the dielectric material as the dummy gate electrode layers 122, and the hard mask layer 124 may be formed over the conductive material. Next, the dielectric material and the conductive material may be patterned through the hard mask layer 124 to form the dummy gate structures 118.

Next, as shown in FIG. 1F, after the dummy gate structures 118 are formed, gate spacer layers 126 are formed along and covering opposite sidewalls of the dummy gate structure 118 and fin spacer layers 128 are formed along and covering opposite sidewalls of the source/drain regions of the fin structure 104, in accordance with some embodiments.

The gate spacer layers 126 may be configured to separate source/drain (S/D) structures from the first dummy gate structure 118a, the second dummy gate structures 118b and support the first dummy gate structure 118a, the second dummy gate structures 118b, and the fin space layers 128 may be configured to constrain a lateral growth of subsequently formed source/drain structure and support the first fin structure 104a and the second fin structure 104b.

In some embodiments, the gate spacer layers 126 and the fin spacer layers 128 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. The formation of the gate spacer layers 126 and the fin spacer layers 128 may include conformally depositing a dielectric material covering the first dummy gate structure 118a, the second dummy gate structure 118b, the first fin structure 104a, the second fin structure 104b and the isolation structure 116 over the substrate 102, and performing an anisotropic etching process, such as dry plasma etching, to remove the dielectric layer covering the top surfaces of the first dummy gate structure 118a, the second dummy gate structure 118b, the first fin structure 104a, the second fin structure 104b, and portions of the isolation structure 116.

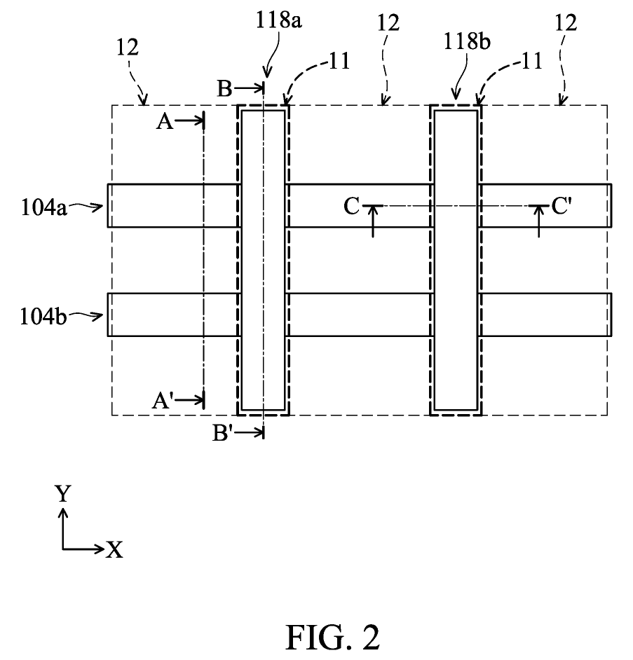

FIG. 2 shows a top-view representation of the semiconductor structure 100a, in accordance with some embodiments. As shown in FIG. 2, the substrate 102 has a first region 11 and a second region 12. The first region 11 is the gate region, and the second region 12 is the S/D region. The first fin structure 104a is formed along a first direction (e.g. X-axis), and the second fin structure 104b is formed along the first direction (e.g. X-axis). A first dummy gate structure 118a and a second dummy gate structure 118b are formed along a second direction (e.g. Y-axis). The second direction (e.g. Y-axis) is orthogonal to the first direction (e.g. X-axis). The first dummy gate structure 118a and the second dummy gate structure 118b are located at the first region 11. The first dummy gate structure 118a and the second dummy gate structure 118b are formed across the first fin structure 104a and the second fin structure 104b. The S/D structures (formed later) will be formed in the second region 12 (the S/D region).

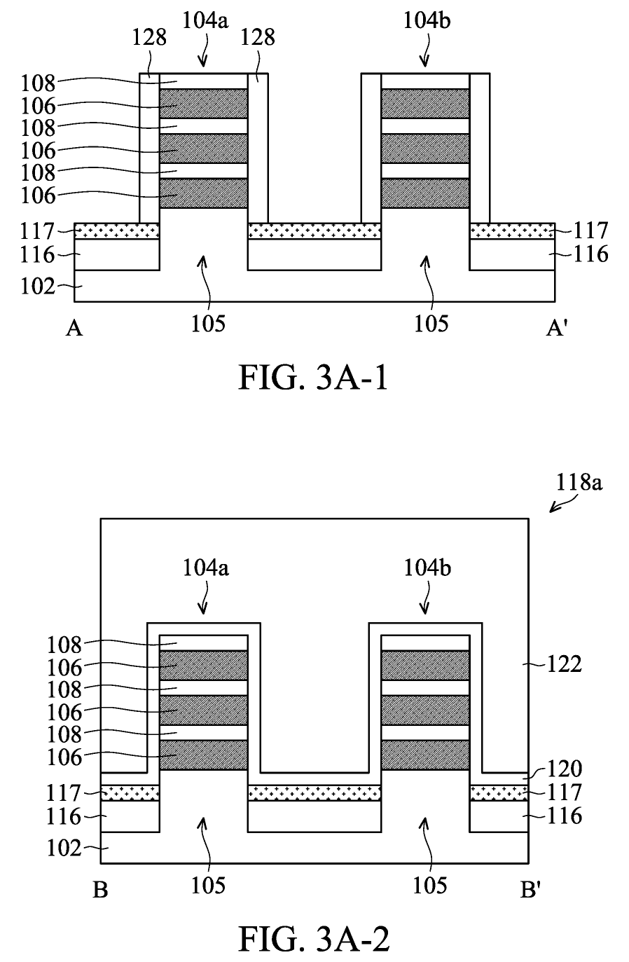

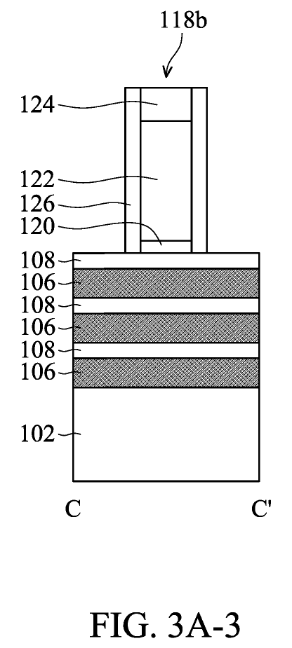

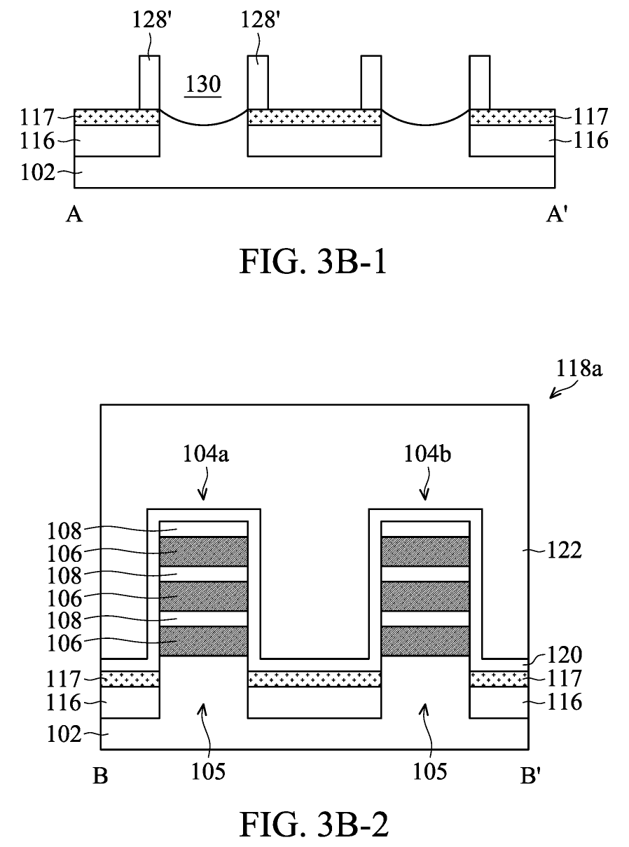

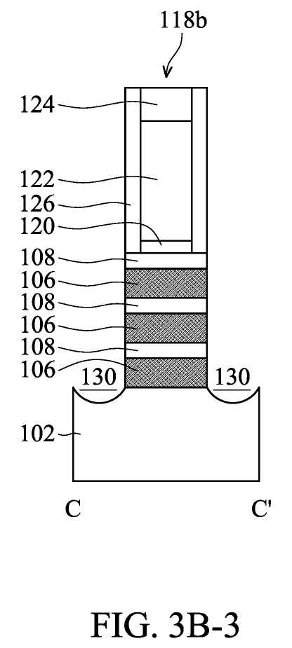

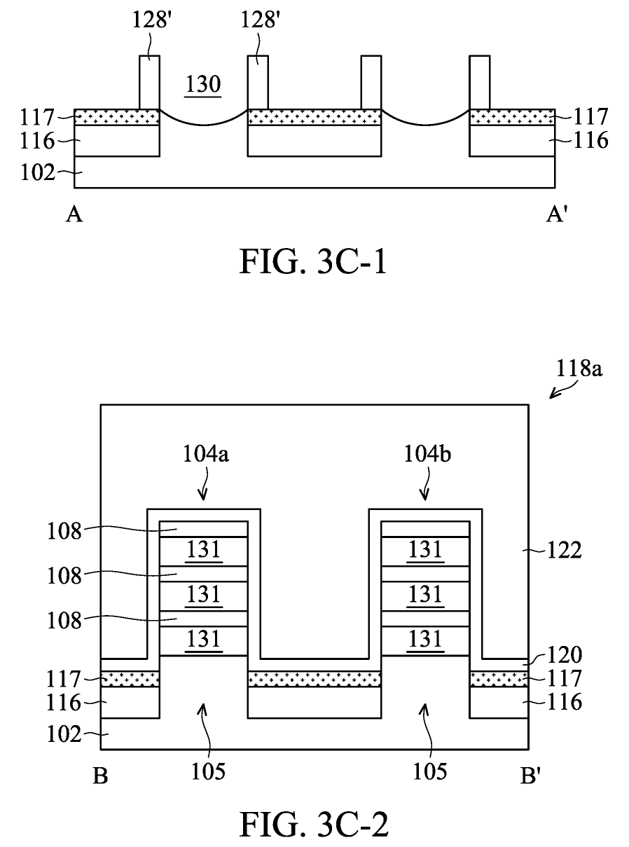

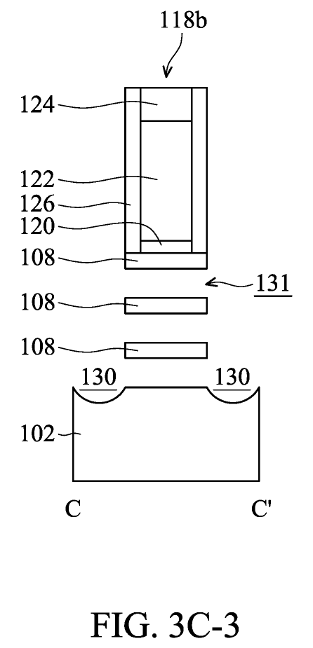

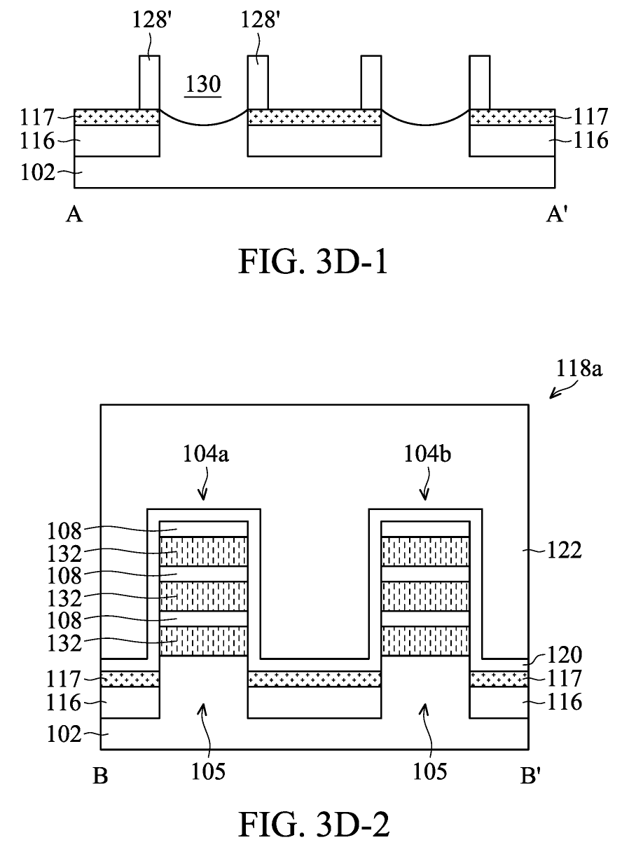

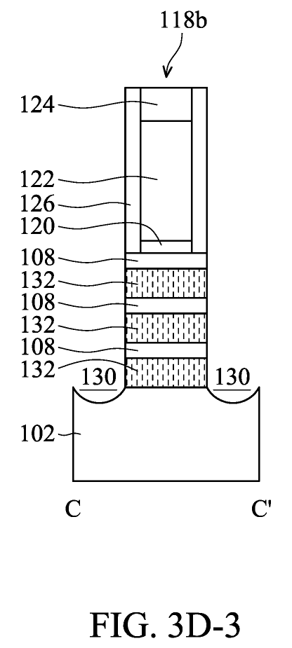

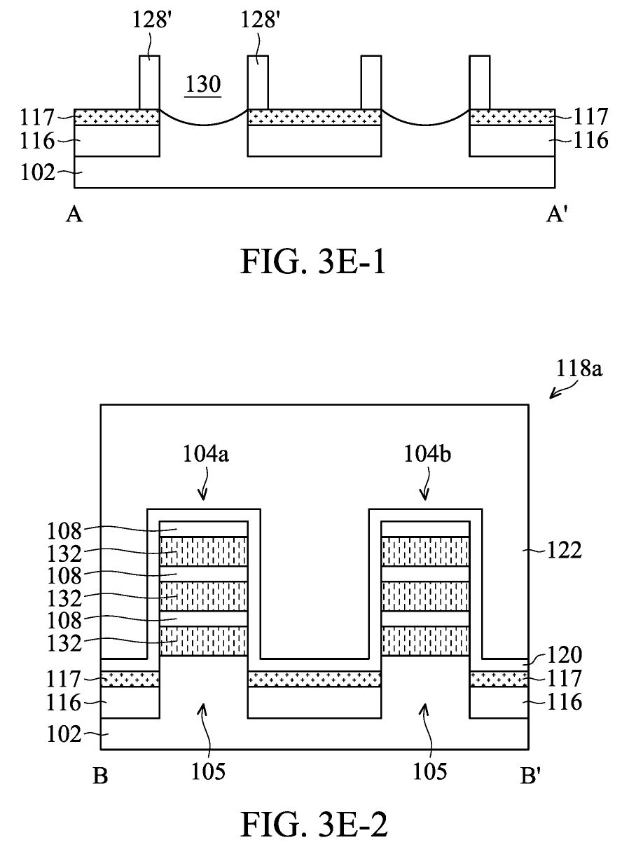

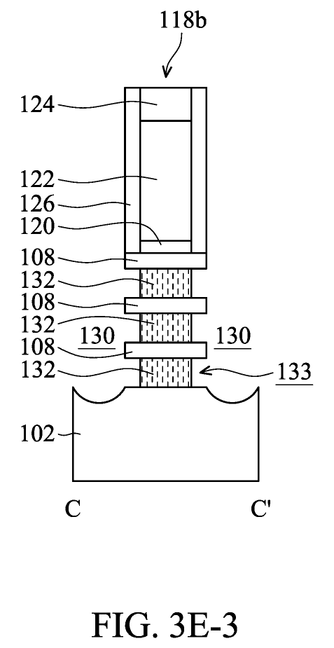

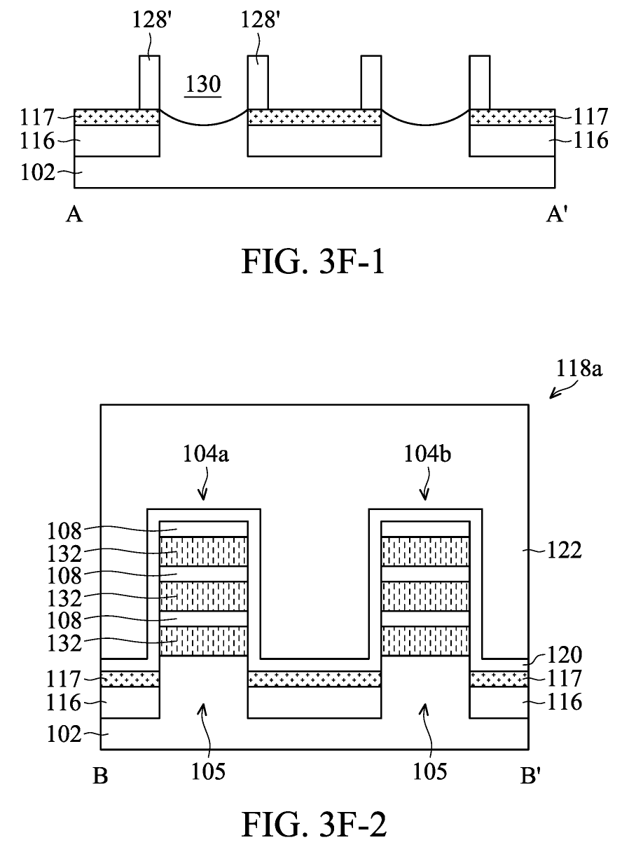

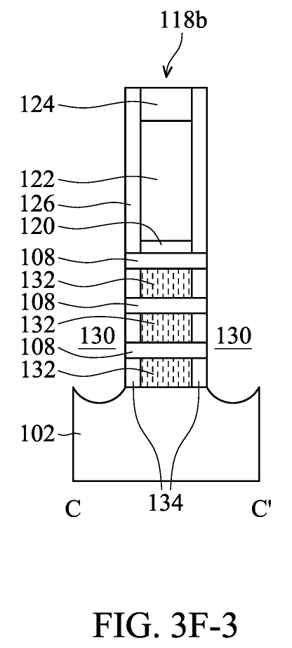

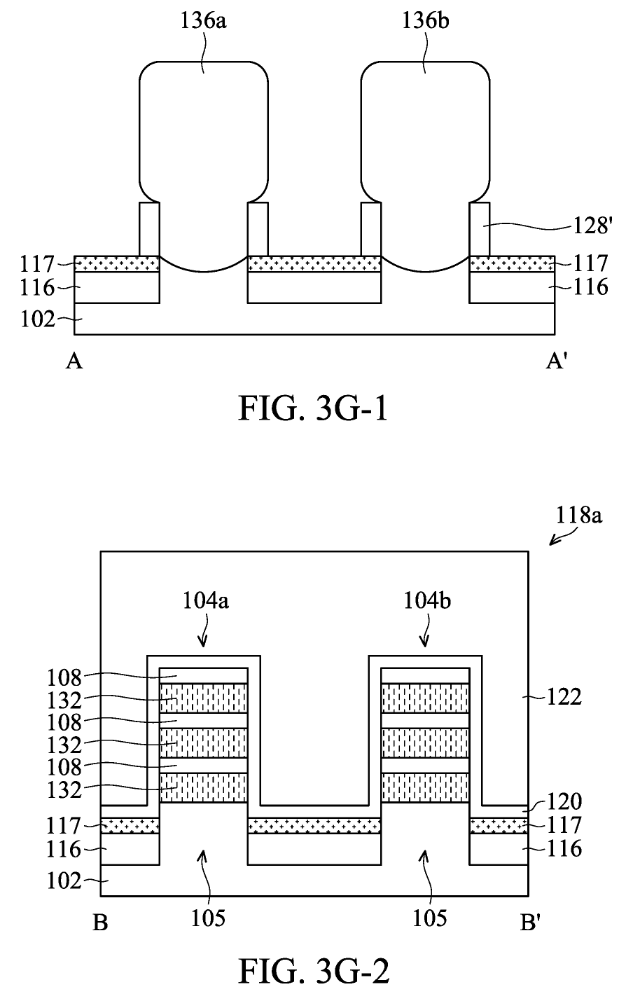

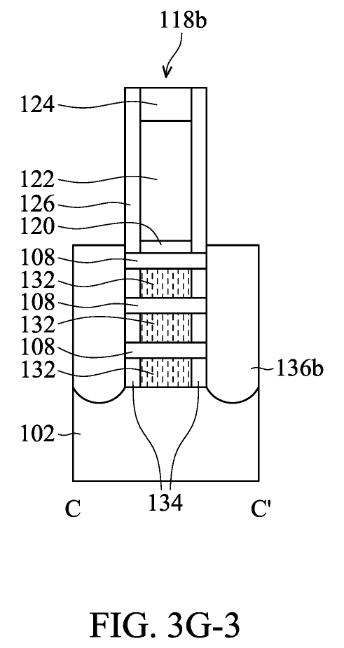

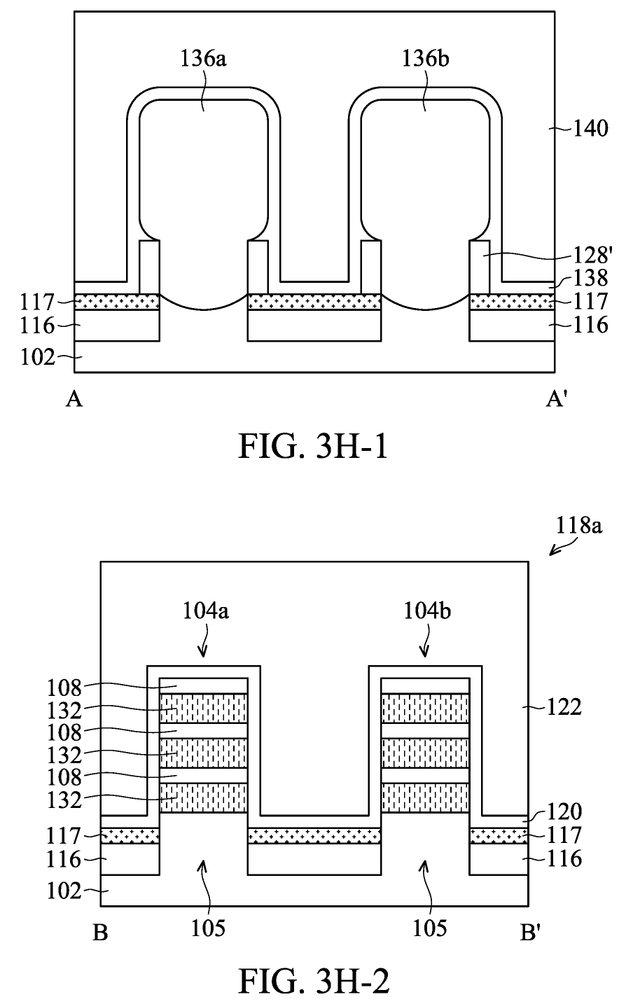

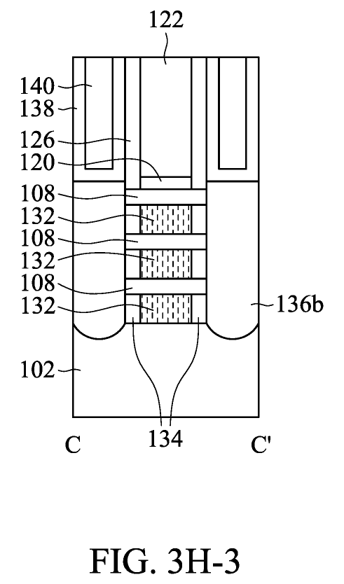

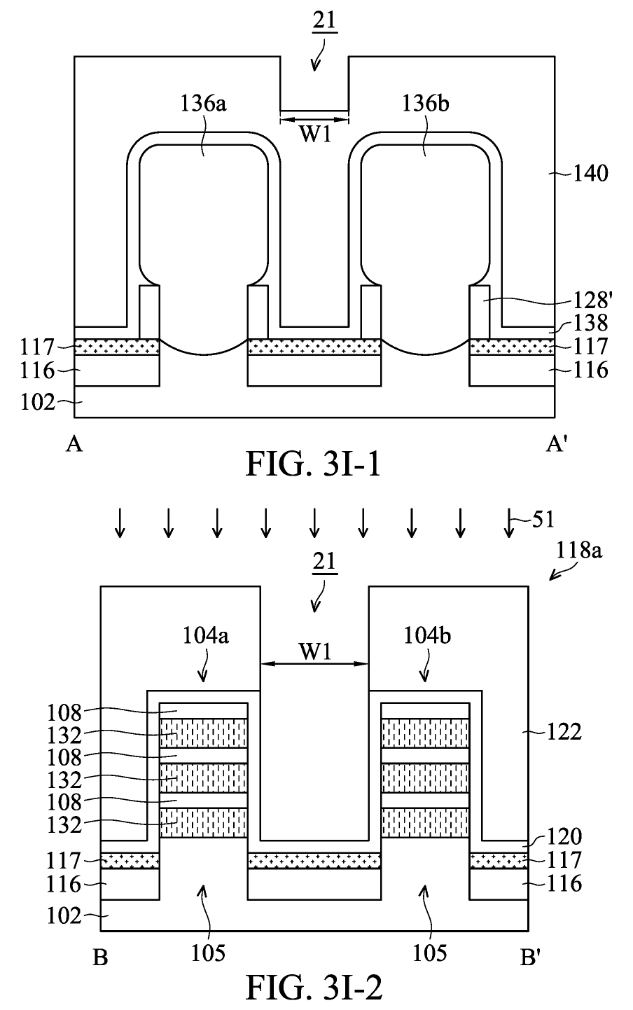

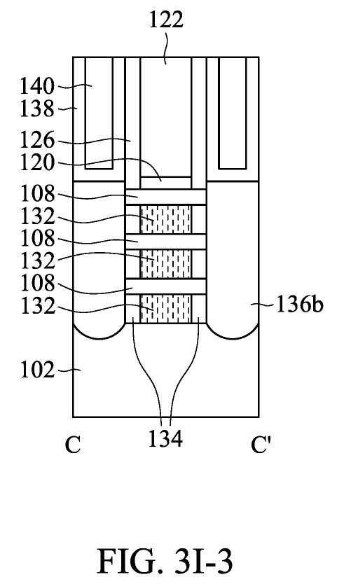

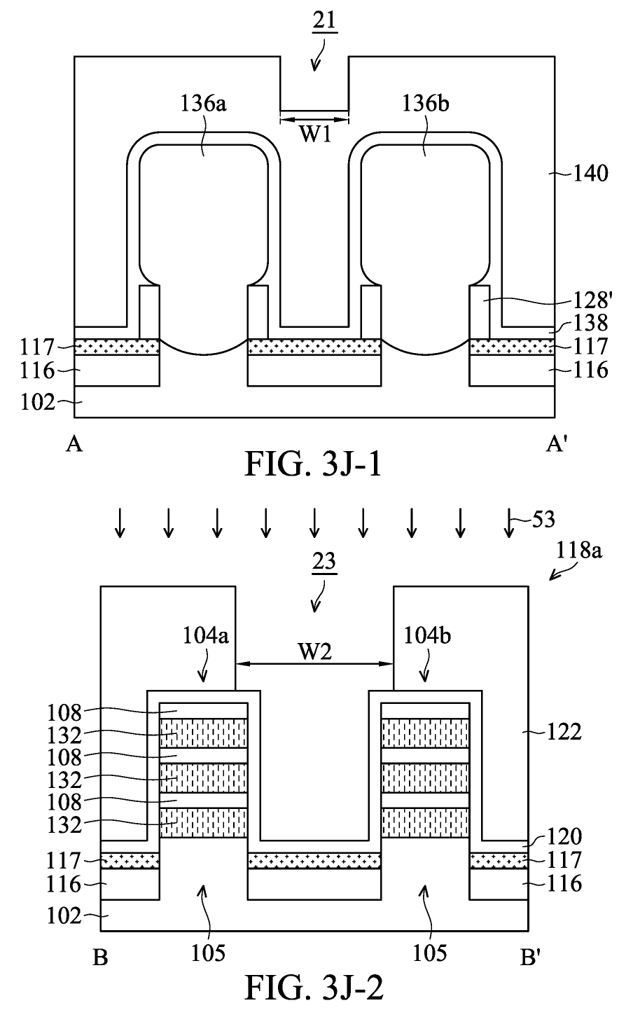

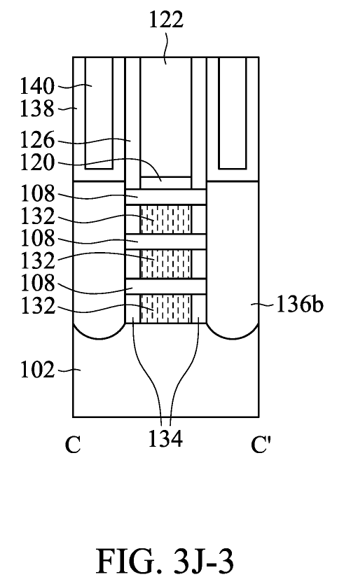

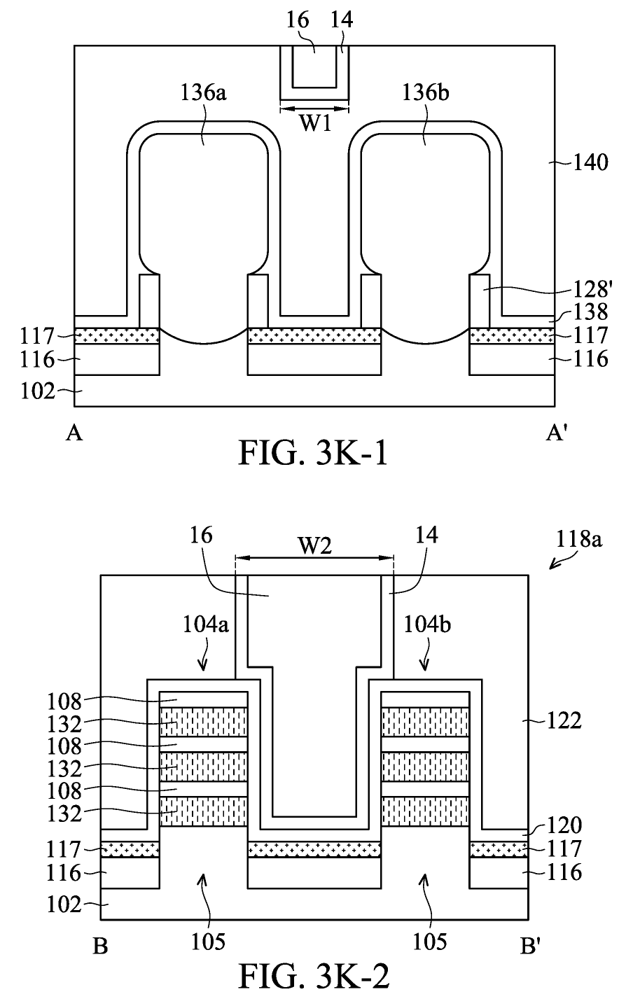

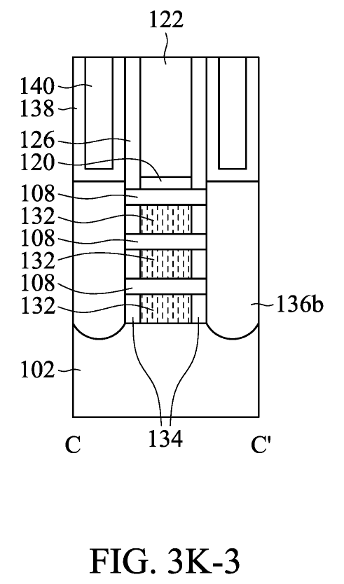

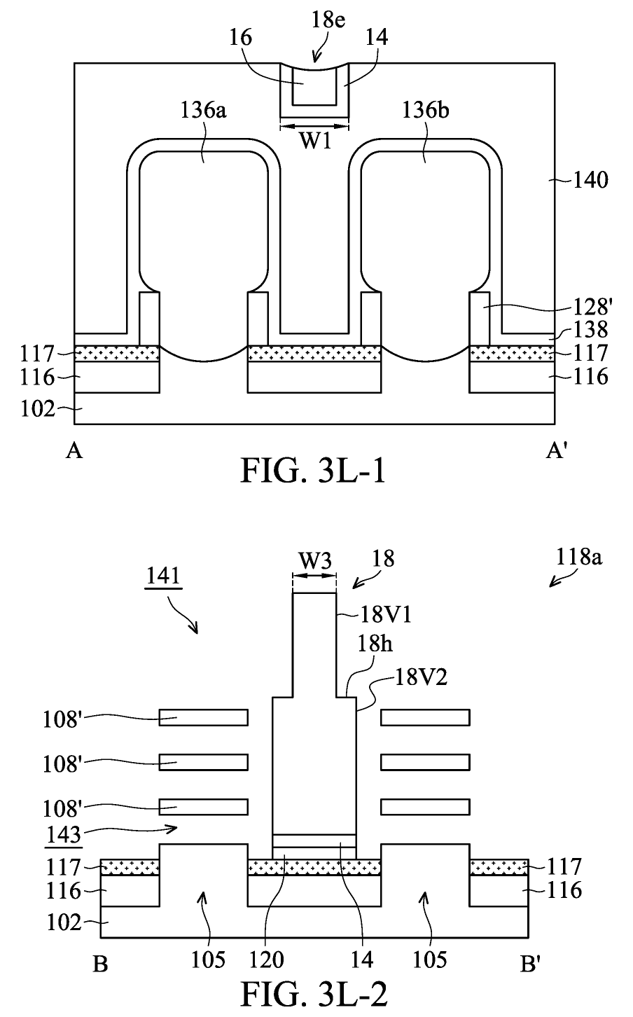

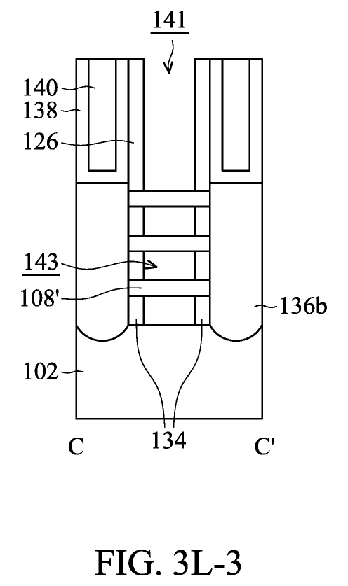

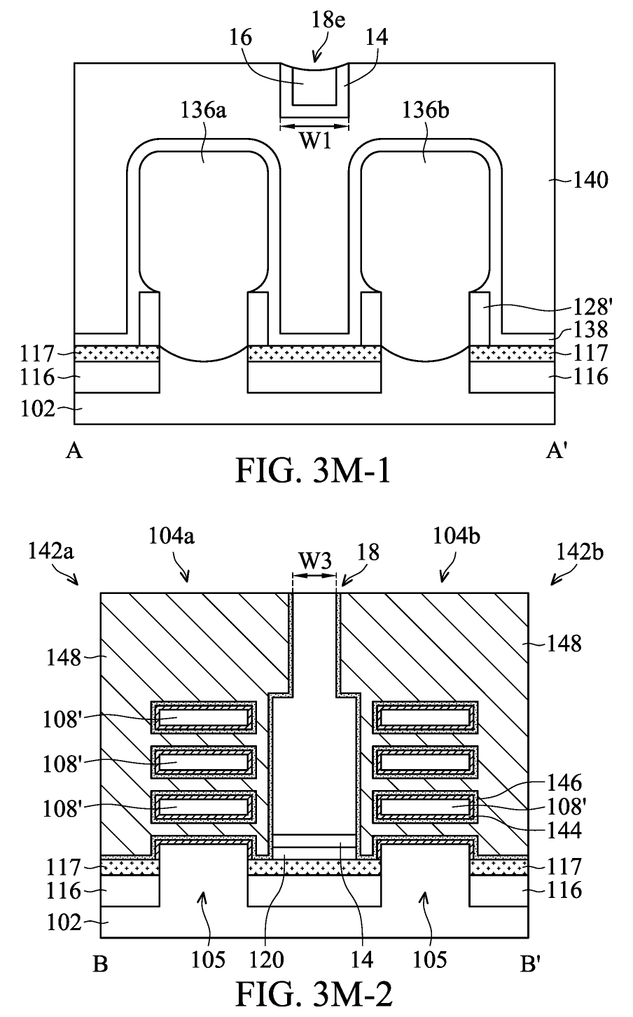

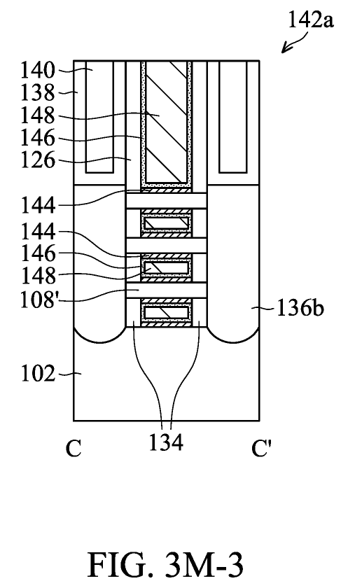

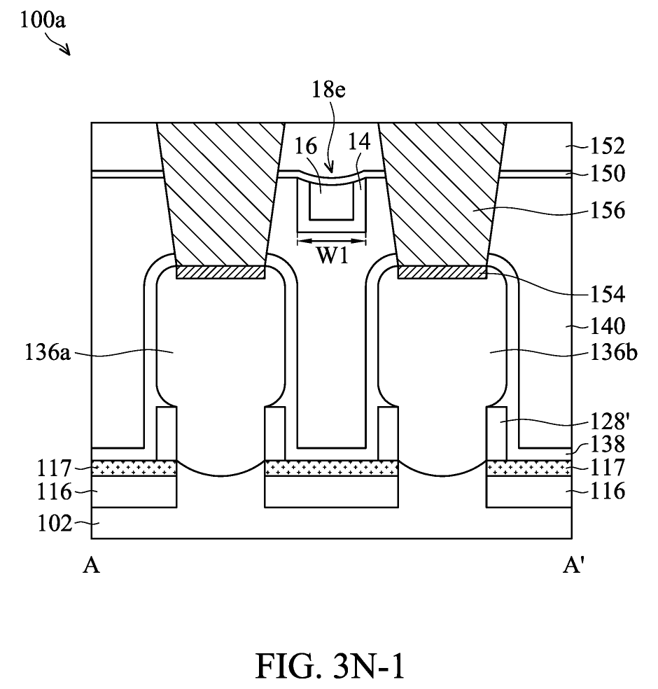

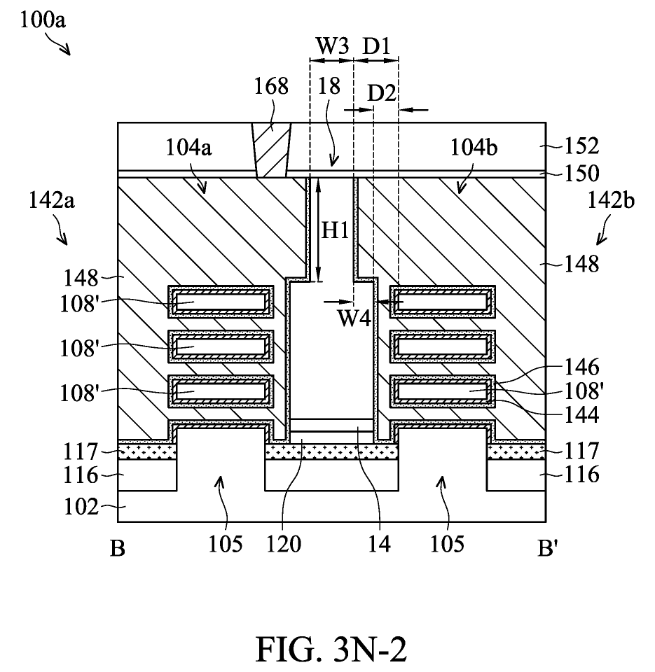

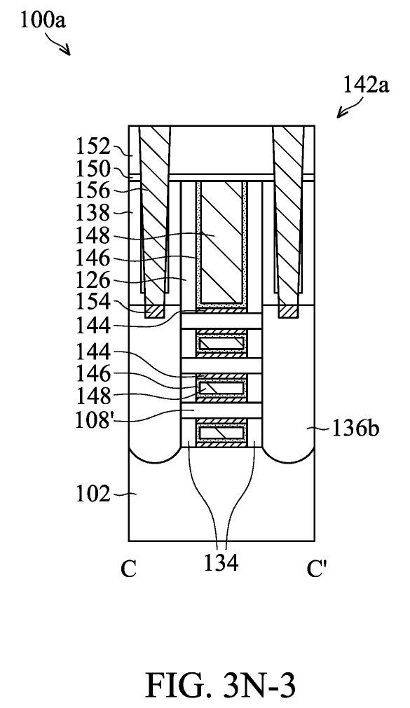

FIGS. 3A-1 to FIGS. 3N-1 illustrate cross-sectional representations of various stages of manufacturing the semiconductor structure 100a shown along line A-A’ in FIG. 1F and in FIG. 2, in accordance with some embodiments. FIGS. 3A-2 to FIGS. 3N-2 illustrate cross-sectional representations of various stages of manufacturing the semiconductor structure 100a shown along line B-B’ in FIG. 1F and in FIG. 2, in accordance with some embodiments. FIGS. 3A-3 to FIGS. 3N-3 illustrate cross-sectional representations of various stages of manufacturing the semiconductor structure 100a shown along line C-C’ in FIG. 1F and in FIG. 2, in accordance with some embodiments.

More specifically, FIG. 3A-1 illustrates the cross-sectional representation shown along line A-A’ in FIG. 1F and FIG. 2. FIG. 3A-2 illustrates the cross-sectional representation shown along line B-B’ in FIG. 1F and FIG. 2 in accordance with some embodiments. FIG. 3A-3 illustrates the cross-sectional representation shown along line C-C’ in FIG. 1F and in FIG. 2.

Next, as shown in FIGS. 3B-1, 3B-2 and 3B-3, after the gate spacer layers 126 and the fin spacer layers 128 are formed, the source/drain (S/D) regions of the fin structure 104 are recessed to form source/drain (S/D) recesses 130, as shown in in accordance with some embodiments. More specifically, the first semiconductor material layers 106 and the second semiconductor material layers 108 not covered by the dummy gate structures 118 and the gate spacer layers 126 are removed, in accordance with some embodiments. In addition, some portions of the base fin structure 105 are also recessed to form curved top surfaces, as shown in FIG. 3B-1 in accordance with some embodiments.

In some embodiments, a portion of the first fin structure 104a and a portion of the second fin structure 104b are recessed by performing an etching process. The etching process may be an anisotropic etching process, such as dry plasma etching, and the first dummy gate structure 118a, the second dummy gate structure 118b and the gate spacer layers 126 are used as etching masks during the etching process. In some embodiments, the fin spacer layers 128 are also recessed to form lowered fin spacer layers 128’.

Afterwards, as shown in FIGS. 3C-1, 3C-2 and 3C-3, after the source/drain recess 130 are formed, the first semiconductor material layers 106 are removed to form a recess 131, in accordance with some embodiments. The recess 131 is exposed by the S/D recess 130.

Next, as shown in FIGS. 3D-1, 3D-2 and 3D-3, a dummy dielectric layer 132 is formed in the recess 131, in accordance with some embodiments. The dummy dielectric layer 132 is used to replace the first semiconductor material layers 106. As a result, the second semiconductor material layers 108 and the dummy dielectric layer 132 are alternately stacked. The dummy dielectric layer 132 is also called as disposable interposer which will be removed and replaced with a first gate structure 142a and a second gate structure 142b (shown in FIGS. 3N-2 and 3N-3) in the following steps.

The dummy dielectric layer 132 is made of silicon oxide (SiO₂), silicon oxynitride (SiON), aluminum oxide (Al₂O₃) or another applicable materials. In some embodiments, the dummy dielectric layer 132 is formed by an ALD (atomic layer deposition process), flowable CVD or another application process. The advantage of the ALD process is to form uniform and conformal films in the narrow recess 131.

Afterwards, as shown in FIGS. 3E-1, 3E-2 and 3E-3, after the dummy dielectric layer 132 is formed, the dummy dielectric layer 132 exposed by the source/drain recesses 130 are laterally recessed to form notches 133, in accordance with some embodiments.

In some embodiments, during the etching process, the second semiconductor material layers 108 have a greater etching rate (or etching amount) than the dummy dielectric layer 132, thereby forming notches 133 between adjacent dummy dielectric layer 132. In some embodiments, the etching process is an isotropic etching such as dry chemical etching, remote plasma etching, wet chemical etching, another suitable technique, and/or a combination thereof.

Next, as shown in FIGS. 3F-1, 3F-2 and 3F-3, inner spacers 134 are formed in the notches 133 between the second semiconductor material layers 108, in accordance with some embodiments. The inner spacers 134 are configured to separate the source/drain (S/D) structures and the gate structures formed in subsequent manufacturing processes in accordance with some embodiments.

In some embodiments, the inner spacers 134 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the inner spacer 134 is formed by a deposition process, such as chemical vapor deposition (CVD) process, atomic layer deposition (ALD) process, another applicable process, or a combination thereof.

Afterwards, as shown in FIGS. 3G-1, 3G-2 and 3G-3, after the inner spacers 134 are formed, a first source/drain (S/D) structure 136a and a second S/D structure 136b are formed in the S/D recesses 130, in accordance with some embodiments.

In some embodiments, the first source/drain (S/D) structure 136a and the second S/D structure 136b are is formed using an epitaxial growth process, such as Molecular beam epitaxy (MBE), Metal-organic Chemical Vapor Deposition (MOCVD), Vapor-Phase Epitaxy (VPE), other applicable epitaxial growth process, or a combination thereof. In some embodiments, the first source/drain (S/D) structure 136a and the second S/D structure 136b are made of any applicable material, such as Ge, Si, GaAs, AlGaAs, SiGe, GaAsP, SiP, SiC, SiCP, or a combination thereof.

In some embodiments, the first source/drain (S/D) structure 136a and the second S/D structure 136b are is in-situ doped during the epitaxial growth process. For example, the first source/drain (S/D) structure 136a and the second S/D structure 136b may be the epitaxially grown SiGe doped with boron (B). For example, the first source/drain (S/D) structure 136a and the second S/D structure 136b may be the epitaxially grown Si doped with carbon to form silicon:carbon (Si:C) source/drain features, phosphorous to form silicon:phosphor (Si:P) source/drain features, or both carbon and phosphorous to form silicon carbon phosphor (SiCP) source/drain features. In some embodiments, the first source/drain (S/D) structure 136a and the second S/D structure 136b are doped in one or more implantation processes after the epitaxial growth process.

Afterwards, as shown in FIGS. 3H-1, 3H-2 and 3H-3, a contact etch stop layer (CESL) 138 is conformally formed to cover the first S/D structures 136a, the second S/D structure 136b and an interlayer dielectric (ILD) layer 140 is formed over the contact etch stop layers 138, in accordance with some embodiments.

In some embodiments, the contact etch stop layer 138 is made of a dielectric materials, such as silicon nitride, silicon oxide, silicon oxynitride, another suitable dielectric material, or a combination thereof. The dielectric material for the contact etch stop layers 138 may be conformally deposited over the semiconductor structure by performing chemical vapor deposition (CVD), ALD, other application methods, or a combination thereof.

The ILD layer 140 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The ILD layer 140 may be formed by chemical vapor deposition (CVD), physical vapor deposition, (PVD), atomic layer deposition (ALD), or other applicable processes.

After the contact etch stop layer 138 and the ILD layer 140 are deposited, a planarization process such as CMP or an etch-back process may be performed until the dummy gate electrode layers 122 of the dummy gate structures 118 are exposed, as shown in FIG. 3I-3 in accordance with some embodiments.

Afterwards, as shown in FIGS. 3I-1, 3I-2 and 3I-3, a portion of the dummy gate electrode layer 122 of the first dummy gate structure 118a is removed to form an opening 21, in accordance with some embodiments. As a result, a portion of the dummy gate dielectric layer 120 is exposed by the opening 21. The opening 21 is formed by a photolithography process and an etching process. The photolithography process includes photoresist coating (e.g., spin-on coating), soft baking, mask aligning, exposure, post-exposure baking, developing the photoresist, rinsing and drying (e.g., hard baking). The etching process includes a dry etching process or a wet etching process.

The portion of the dummy gate electrode layer 122 of the first dummy gate structure 118a is removed by performing a first etching process 51. In addition, a portion of the ILD layer 140 is also removed by the first etching process 51. Therefore, the opening 21 extends from the first region 11 (the gate region) to the second region 12 (the S/D region).

In some embodiments, when the dummy gate electrode layer 122 is polysilicon, a wet etchant such as a tetramethylammonium hydroxide (TMAH) solution may be used to selectively remove the dummy gate electrode layer 122.

In some embodiments, the opening 21 has a rectangular structure with uniform thickness from top to bottom. In some embodiments, the top portion of the opening 21 has a width W₁ along the second direction (e.g. y-axis). Although the ILD layer 140 is removed, the removal amount of the ILD layer 140 is smaller than the removal amount of the dummy gate electrode layer 122. Since the ILD layer 140 has an etching selectivity with respect to the dummy gate electrode layer 122, the ILD layer 140 is etched less than the dummy gate electrode layer 122. In other words, the ILD layer 140 is hard to be removed with respect to the dummy gate electrode layer 122. Therefore, the depth of the opening 21 in the S/D region (shown in FIG. 3I-1) is smaller than the depth of the opening 21 in the gate region (shown in FIG. 3I-2).

The term of “selectivity” or “etching selectivity” is defined as the ratio of etching rate of one material (the reference material) relative to another material (the material of interest). An increase in etching selectivity means that the selected material, or material of interest, is harder to etch. A decrease in etching selectivity means that the selected material is easier to etch.

Next, as shown in FIGS. 3J-1, 3J-2 and 3J-3, the sidewall portion of the dummy gate electrode layer 122 is further removed to form an opening 23, in accordance with some embodiments. The opening 23 has a T-shaped structure with a top portion and a bottom portion, and the top portion is wider than the bottom portion. In the S/D region (shown in FIG. 3J-1), the opening 21 is not enlarged. In the gate region (shown in FIG. 3J-2), the opening 23 is wider than the opening 21. The top portion of the opening 23 has a width W2, and the second width W2 is greater than the first width W1.

The opening 23 is formed by a photolithography process and an etching process. The photolithography process includes photoresist coating (e.g., spin-on coating), soft baking, mask aligning, exposure, post-exposure baking, developing the photoresist, rinsing and drying (e.g., hard baking). The etching process includes a dry etching process or a wet etching process.

The sidewall portion of the dummy gate electrode layer 122 of the first dummy gate structure 118a is removed by performing a second etching process 53. In the second etching process 53, the ILD layer 140 has a high etching selectivity with respect to the dummy gate electrode layer 122, the ILD layer 140 is not etched while the sidewall portion of the dummy gate electrode layer 122 is removed.

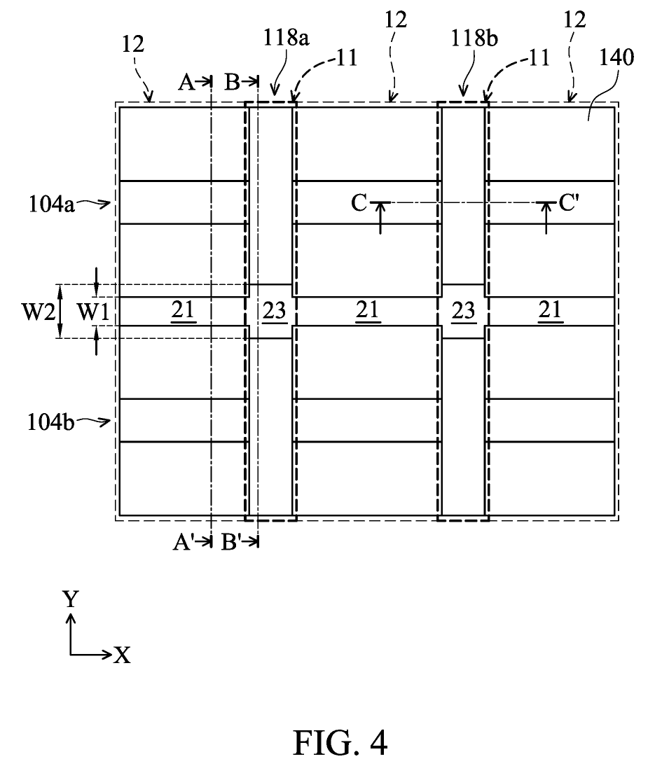

FIG. 4 shows a top-view representation of the semiconductor structure 100a after forming the opening 23, in accordance with some embodiments.

As shown in FIG. 4, in the first region 11 (the gate region), the opening 23 has the second width W2 along the second direction (e.g. Y-axis). In the second region 12 (the S/D region), the opening 21 has the first width W1 along the second direction (e.g. Y-axis). In some embodiments, the second width W2 is greater than the first width W1.

Next, as shown in FIGS. 3K-1, 3K-2 and 3K-3, a liner layer 14 and an dielectric wall material 16 is formed in the opening 21 and the opening 23, in accordance with some embodiments. Next, a portion of the liner layer 14 and a portion of the dielectric wall material 16 are removed by a polishing process, such as CMP or an etch-back process.

The liner layer 14 and the dielectric wall material 16 are made of different materials. In some embodiments, the liner layer 14 is made of SiN, SiCN, SiOC, SiOCN or applicable material. In some embodiments, the dielectric wall material 16 is made of SiN, SiCN, SiOC, SiOCN or applicable material. In some embodiments, the liner layer 14 is made of SiOₓ₁C_{y1}N_{z1}, and the dielectric wall material 16 is made of SiOₓ₂C_{y2}N_{z2}, wherein y1<Y2, Z1<Z2. The nitrogen ratio of the dielectric wall material 16 is greater than the nitrogen ratio of the liner layer 14. The dielectric wall material 16 has a high etching selectivity with respect to liner layer 14. The dielectric wall material 16 is hard to remove when the liner layer 14 is removed.

Afterwards, as shown in FIGS. 3L-1, 3L-2 and 3L-3, the remaining dummy gate electrode layer 122 of the first dummy gate structure 118a is removed, and then the liner layer 14 and the dummy gate dielectric layer 120 are removed, in accordance with some embodiments. The first dummy gate structure 118a and the second dummy gate structure 118b are removed to form a trench 141, in accordance with some embodiments.

The removal process may include one or more etching processes. For example, when the dummy gate electrode layer 122 is polysilicon, a wet etchant such as a tetramethylammonium hydroxide (TMAH) solution may be used to selectively remove the dummy gate electrode layer 122. Afterwards, the dummy gate dielectric layer 120 may be removed using a plasma dry etching, a dry chemical etching, and/or a wet etching.

In addition, the dummy dielectric layer 132 is removed to form nanostructures 108’ (or channel layers 108’) with the second semiconductor material layers 108 when the dummy gate dielectric layer 120 is removed. The top portion of the dielectric wall material 16 is also removed when the dummy gate dielectric layer 120 is removed. As a result, the top portion of the dielectric wall material 16 is removed to form a dielectric wall structure 18. The dielectric wall structure 18 has a reversed T-shaped structure after the removal process.

In some embodiments, as shown in FIG. 3L-2, the dielectric wall structure 18 has a sidewall surface, and the sidewall surface has a top vertical portion 18V1, a horizontal portion 18h, and a bottom vertical portion 18V2. The horizontal portion 18h is between the top vertical portion 18V1 and the bottom vertical portion 18V2. In some embodiments, the horizontal portion 18h of the dielectric wall structure 18 is higher than the topmost surface of the nanostructures 108’. After the removal process, the top surface of the dielectric wall structure 18 has a third width W3. In some embodiments, the third width W3 is smaller than the second width W2. In some embodiments, the third width W3 is smaller than the first width W1. In some other embodiments, the third width W₃ is equal to the first width W₁. In some embodiments, the third width W3 of the top surface of the dielectric wall structure 18 is smaller than the width of the nanostructure 108’. In some embodiments, the third width W3 of the top surface of the dielectric wall structure 18 is greater than the width of the nanostructure 108’.

As shown in FIG. 3L-1, the dielectric wall structure 18 has an extending portion 18e which is between the first S/D structure 136a and the second S/D structure 136b. The bottom surface of the extending portion 18e is higher than the top surface of the first S/D structure 136a and the top surface of the second S/D structure 136b.

It should be noted that a portion of the liner layer 14 is directly below the dielectric wall structure 18 and not removed, and therefore the remaining liner layer 14 is left directly below the dielectric wall structure 18. In addition, the remaining portion of the dummy gate dielectric layer 120 directly below the liner layer 14 is also left. The sidewall surface of the remaining liner layer 14 is substantially aligned with the sidewall surface of the remaining dummy gate dielectric layer 120.

As shown in FIG. 3L-1, the top portion of the liner layer 14 and the top portion of the dielectric wall material 16 are slightly removed. Therefore, the top surface of the liner layer 14 and the top portion of the dielectric wall material 16 are recessed.

Next, as shown in FIGS. 3M-1, 3M-2 and 3M-3, after the nanostructures 108’ are formed, a first gate structure 142a and a second gate structure 142b are formed to surround the nanostructures 108’, in accordance with some embodiments.

An interfacial layers 144, an gate dielectric layers 146, and an gate electrode layers 148 are formed to surround the nanostructures 108’, and then a planarization process such as CMP or an etch-back process may be performed until the ILD layer 140 is exposed. As a result, the dielectric wall structure 18 is formed between the first gate structure 142a and the second gate structure 142b. In some embodiments, the first gate structure 142a includes an interfacial layer 144, a gate dielectric layer 146, and a gate electrode layer 148. In some embodiments, the second gate structure 142b includes the interfacial layer 144, the gate dielectric layer 146, and the gate electrode layer 148.

The first gate structure 142a and the second gate structure 142b are formed wrapped around the nanostructures 108’. The first gate structure 142a and the second gate structure 142b wrap around the nanostructures 108’ to form gate-all-around transistor structures in accordance with some embodiments.

In some embodiments, the interfacial layers 144 are oxide layers formed around the nanostructures 108’ and on the top of the base fin structure 105. In some embodiments, the interfacial layers 144 are formed by performing a thermal process.

In some embodiments, the gate dielectric layers 146 are formed over the interfacial layers 144, so that the nanostructures 108’ are surrounded (e.g. wrapped) by the gate dielectric layers 146. In addition, the gate dielectric layers 146 also cover the sidewalls of the gate spacers 126 and the inner spacers 134 in accordance with some embodiments. In some embodiments, the gate dielectric layers 146 are made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂-Al2O₃) alloy, another suitable high-k dielectric material, or a combination thereof. In some embodiments, the gate dielectric layers 146 are formed using chemical vapor deposition (CVD), atomic layer deposition (ALD), another applicable method, or a combination thereof.

In some embodiments, the gate electrode layers 148 are made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. In some embodiments, the gate electrode layers 148 are formed using chemical vapor deposition (CVD), atomic layer deposition (ALD), electroplating, another applicable method, or a combination thereof.

Other conductive layers, such as work function metal layers, may also be formed in the first gate structure 142a and the second gate structure 142b, although they are not shown in the figures. In some embodiments, the n-work function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAlN), tantalum carbon nitride (TaCN), tantalum silicon nitride (TaSiN), manganese (Mn), zirconium (Zr) or a combination thereof. In some embodiments, the p-work function layer includes titanium (Ti), titanium nitride (TiN), tantalum nitride (TaN), tantalum carbide (TaC), molybdenum nitride, tungsten nitride (WN), ruthenium (Ru) or a combination thereof.

Afterwards, as shown in FIGS. 3N-1, 3N-2 and 3N-3, an etch stop layer 150 is formed over the first gate structure 142a and the second gate structure 142b, and a dielectric layer 152 is formed over the etch stop layer 150, in accordance with some embodiments.

In some embodiments, the etch stop layer 150 is made of a dielectric materials, such as silicon nitride, silicon oxide, silicon oxynitride, another suitable dielectric material, or a combination thereof. The dielectric material for the etch stop layers 150 may be conformally deposited over the semiconductor structure by performing chemical vapor deposition (CVD), ALD, other application methods, or a combination thereof.

The dielectric layer 152 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The dielectric layer 152 may be formed by chemical vapor deposition (CVD), physical vapor deposition, (PVD), atomic layer deposition (ALD), or other applicable processes.

Next, a silicide layer 154 and an S/D contact structure 156 are formed over the first S/D structure 136a and the second S/D structure 136b, and a gate contact structure 168 is formed over the first gate structure 142a and the second gate structure 142b, in accordance with some embodiments. The gate contact structure 168 is electrically connected to the first gate structure 142a.

In some embodiments, the contact openings may be formed through the contact etch stop layer 138, the interlayer dielectric layer 140, the etch stop layer 150 and the dielectric layer 152 to expose the top surfaces of the first S/D structures 136a and the second S/D structure 136b, and then the silicide layers 154 and the S/D contact structure 156 may be formed in the contact openings. The contact openings may be formed using a photolithography process and an etching process. In addition, some portions of the first S/D structure 136a and second S/D structure 136b exposed by the contact openings may also be etched during the etching process.

The silicide layers 154 may be formed by forming a metal layer over the top surfaces of the first S/D structure 136a and the second S/D structure 136b and annealing the metal layer so the metal layer reacts with the first S/D structure 136a and the second S/D structure 136b to form the silicide layers 154. The unreacted metal layer may be removed after the silicide layers 154 are formed.

The S/D contact structure 156 may include a barrier layer and a conductive layer. In some other embodiments, the S/D contact structure 156 does not include a barrier layer. In some embodiments, the barrier layer is made of titanium (Ti), titanium nitride (TiN), tantalum (Ta), tantalum nitride (TaN), or another applicable material. In some embodiments, the barrier layer is formed by using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes. In some embodiments, the conductive layer is made of tungsten (W), ruthenium (Ru), molybdenum (Mo), or the like. In some embodiments, the conductive layer is formed by performing a deposition process, such as chemical vapor deposition (CVD), physical vapor deposition, (PVD), atomic layer deposition (ALD), or other applicable processes.

In some embodiments, the gate contact structure 168 is made of conductive material, such as tungsten (W), ruthenium (Ru), molybdenum (Mo), or the like. In some embodiments, the gate contact structure 168 is formed by performing a deposition process, such as chemical vapor deposition (CVD), physical vapor deposition, (PVD), atomic layer deposition (ALD), or other applicable processes.

As shown in FIG. 3N-2, the dielectric wall structure 18 has a top portion and a bottom portion, and the bottom portion is wider than the top portion. The dielectric wall structure 18 has a reversed-T shaped structure. In some embodiments, the dielectric wall structure 18 has a sidewall surface, and the sidewall surface has a top vertical portion 18V1, a horizontal portion 18h, and a bottom vertical portion 18V2. The horizontal portion 18h is between the top vertical portion 18V1 and the bottom vertical portion 18V2. In some embodiments, the horizontal portion 18h of the dielectric wall structure 18 is higher than the topmost surface of the nanostructures 108’.

Furthermore, the dielectric wall structure 18 has a top portion and a bottom portion, there is a first distance D1 between the sidewall surface of the top portion and the sidewall surface of the topmost nanostructure 108’. There is a second distance D2 between the sidewall surface of the bottom portion and the sidewall surface of the topmost nanostructure 108’. In some embodiments, the first distance D1 is greater than the second distance D2. In some embodiments, the first distance D1 is in a range from about 4 nm to about 8 nm. When the first distance D1 is within the above mentioned range, the unwanted capacitance of the semiconductor structure 100a is receded.

The top portion of the dielectric wall structure 18 has a first height H1. In some embodiments, the first height H1 is in a range from about 10 nm to about 15 nm. In some embodiments, the third width W3 of the topmost surface of the dielectric wall structure 18 is in a range from about 15 nm to about 45 nm. The horizontal portion 18h of the sidewall surface of the dielectric wall structure 18 has a fourth width W4. In some embodiments, the fourth width W4 is a range from about 5 nm to about 30 nm.

Since the dielectric wall structure 18 is formed before the first gate structure 142a is formed, the gate dielectric layer 146 of the first gate structure 142a is in contact with the sidewall surface of the bottom portion of the dielectric wall structure 18 and the sidewall surface of the top portion of the dielectric wall structure 18. In addition, the liner layer 14 is directly below the dielectric wall structure 18, and the gate dielectric layer 146 of the first gate structure 142a is in contact with the sidewall surface of the liner layer 14. The dummy gate dielectric layer 120 is also directly below the dielectric wall structure 18 and the liner layer 14, and the gate dielectric layer 146 of the first gate structure 142a is in contact with the sidewall surface of the dummy gate dielectric layer 120.

As shown in FIG. 3N-2, the mask layer 117 is formed on the isolation structure 116, and the liner layer 14 is on the mask layer 117. The dielectric wall structure 18 is on the mask layer 117. The liner layer 14 is between the mask layer 117 and the dielectric wall structure 18. The mask layer 117 is separated from the dielectric wall structure 18 by the liner layer 14 and the dummy gate dielectric layer 120. The mask layer 117 is between the isolation structure 116 and the dielectric wall structure 18. The dummy gate dielectric layer 120 is between the liner layer 14 and the mask layer 117.

It should be noted that since the top portion of the dielectric wall structure 18 is removed or trimmed, the top width of the top surface of the dielectric wall structure 18 is reduced, and therefore there will be more space for forming the gate contact structure 168. The gate contact structure 168 is formed on the first gate structure 142a and is not in contact with the dielectric wall structure 18. Therefore, the gate contact structure 168 has more landing window.

Furthermore, since there is a space (marked as the second distance D2 at FIG. 3N-2) between the sidewall surface of the bottom portion of the dielectric wall structure 18 and the sidewall surface of the topmost nanostructure 108’, the dummy dielectric layers 132 are easily removed at the step of FIG. 3L-2. The issue of the remaining dummy dielectric layers 132 is prevented.

In addition, the dielectric wall structure 18 has a reversed T-shaped structure and the first gate structure 142a is filled into the space between the dielectric wall structure 18 and the nanostructures 108’ to further reduce capacitance. Therefore, the performance of the semiconductor structure 100a is improved.

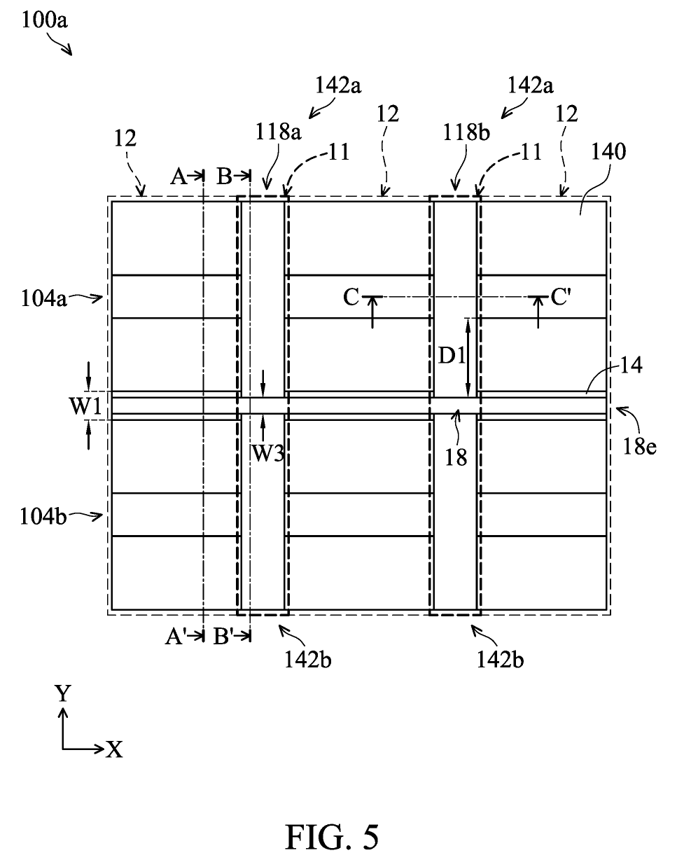

FIG. 5 shows a top-view representation of the semiconductor structure 100a after forming the first gate structure 142a and the second gate structure 142b, in accordance with some embodiments.

As shown in FIG. 5, the dielectric wall structure 18 is between the first gate structure 142a and the second gate structure 142b. The first gate structure 142a is separated from the second gate structure 142b by the dielectric wall structure 18. The longitudinal direction of the dielectric wall structure 18 is along the first direction (e.g. x-axis). The longitudinal direction of the dielectric wall structure 18 is parallel to the longitudinal direction of the first fin structure 104a and the second fin structure 104b.

The dielectric wall structure 18 extends from the first region 11 (the gate region) to the second region 12 (the S/D region). The dielectric wall structure 18 has the first width W₁ at the second region 12 (the S/D region) and the third with W₃ at the first region 11 (the gate region). In some embodiments, the third width W₃ is smaller than the first width W₁.

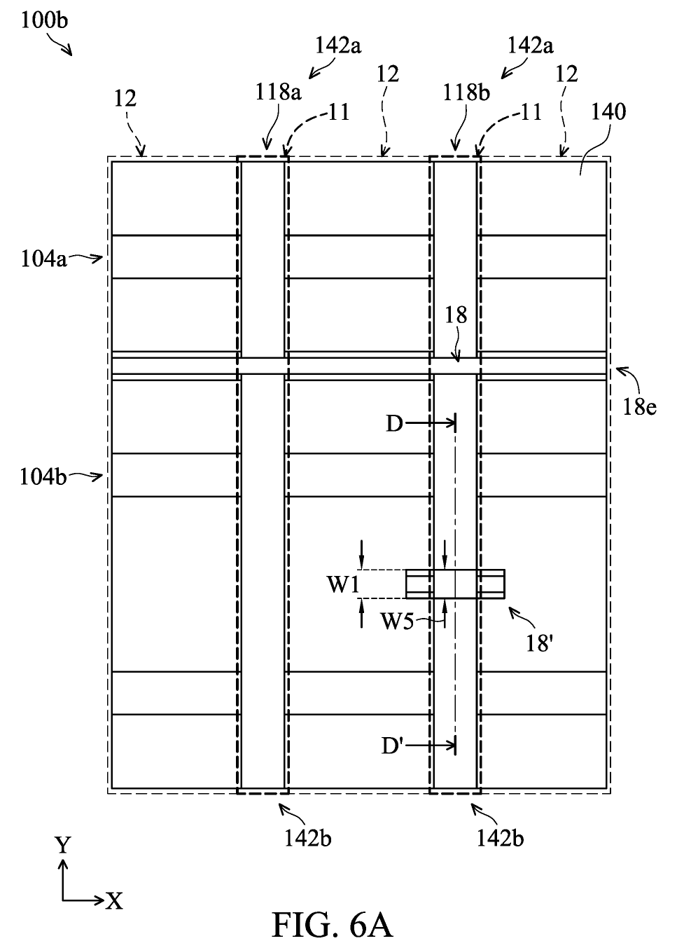

FIG. 6A shows a top-view representation of a semiconductor structure 100b after forming the first gate structure 142a and the second gate structure 142b, in accordance with some embodiments. FIG. 6B illustrates a cross-sectional representation of the semiconductor structure 100b shown along line D-D’ in FIG. 6A, in accordance with some embodiments. The semiconductor structure 100b of FIGS. 6A and 6B includes elements that are similar to, or the same as, elements of the semiconductor structure 100a of FIG. 3N-2 and 5, the difference between FIGS. 6A and 6B and FIGS. 3N-2 and 5 is that the length of the dielectric wall structure 18’ along the first direction (e.g. x-axis) is smaller than the length of the dielectric wall structure 18 along the first direction (e.g. x-axis).

As shown in FIGS. 6A and 6B, the mainly portion of the dielectric wall structure 18’ located at the first region 11 (the gate region). The other portion of the dielectric wall structure 18’ located at the second region 12 (the S/D region). In some embodiments, the dielectric wall structure 18’ has the first width W1 at the second region 12 (the S/D region) and the third with W3 at the first region 11 (the gate region). In some embodiments, the third width W3 is equal to the first width W1.

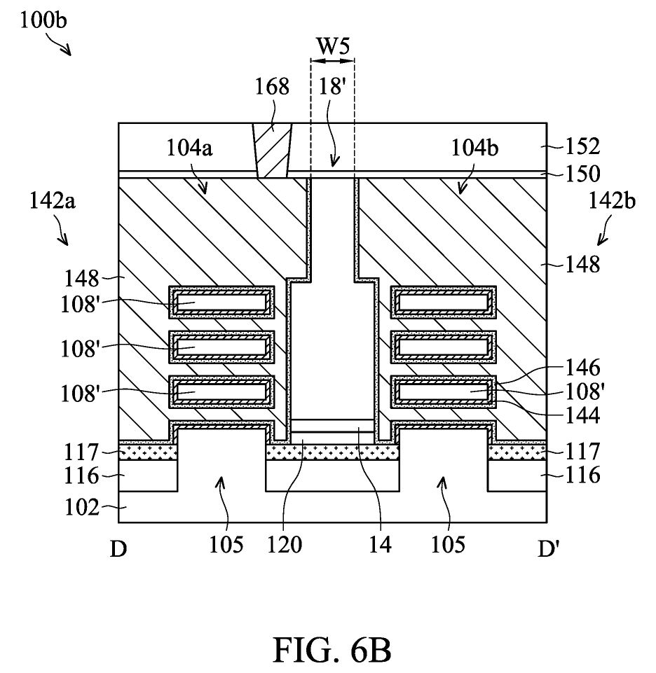

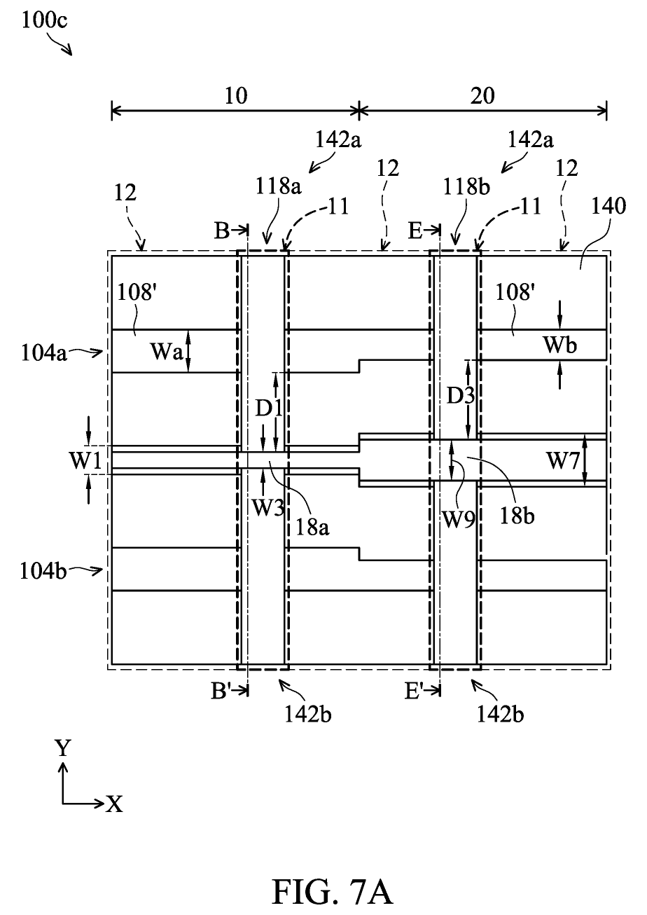

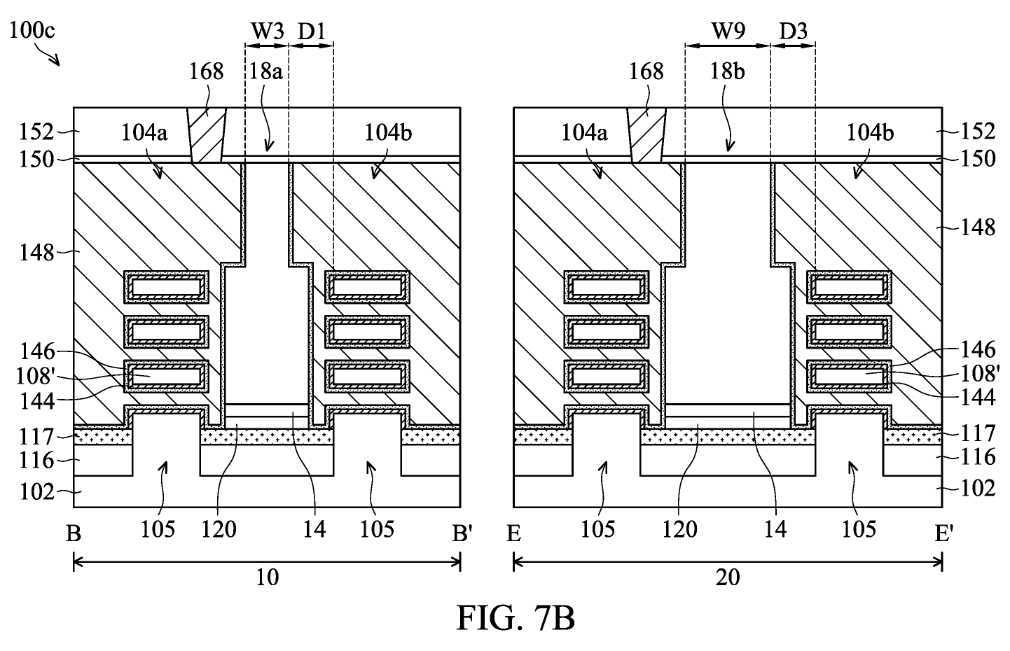

FIG. 7A shows a top-view representation of a semiconductor structure 100c after forming the first gate structure 142a and the second gate structure 142b, in accordance with some embodiments. FIG. 7B illustrates a cross-sectional representation of the semiconductor structure 100c shown along line B-B’ and E-E’ in FIG. 7A, in accordance with some embodiments. The semiconductor structure 100c of FIGS. 7A and 7B includes elements that are similar to, or the same as, elements of the semiconductor structure 100a of FIG. 3N-2 and 5, the difference between FIGS. 7A and 7B and FIGS. 3N-2 and 5 is that the width Wa of the nanostructures 108’ in a first sub-region 10 is greater than the width Wb of the nanostructures 108’ in a second sub-region 20. The width Wa and the width Wb are measured along the second direction (e.g. Y-axis).

In the first sub-region 10, the dielectric wall structure 18a has the first width W1 at the second region 12 (the S/D region) and the third with W3 at the first region 11 (the gate region). In some embodiments, the third width W3 is smaller than the first width W1.

In the second sub-region 20, the dielectric wall structure 18b has the seventh width W7 at the second region 12 (the S/D region) and the ninth with W9 at the first region 11 (the gate region). In some embodiments, the ninth width W9 is smaller than the seventh width W7.

As shown in FIG. 7A, there is the first distance D1 between the sidewall surface of the top portion of the dielectric wall structure 18a and the sidewall surface of the topmost nanostructure 108’. There is a third distance D3 between the sidewall surface of the top portion of the dielectric wall structure 18b and the sidewall surface of the topmost nanostructure 108’. In some embodiments, the first distance D1 is substantially equal to the third distance D3. In some embodiments, the third distance D3 is in a range from about 4 nm to about 8 nm.

As shown in FIG. 7B, the dielectric wall structure 18a and the dielectric wall structure 18b have reversed T-shaped structures. Therefore, the first gate structure 142a is filled into the space between the dielectric wall structure 18a and the nanostructures 108’ to further reduce capacitance. In addition, the gate contact structure 168 is formed on the first gate structure 142a and is not in contact with the dielectric wall structure 18a. Therefore, the gate contact structure 168 has more landing window. Therefore, the performance of the semiconductor structure 100c is improved.

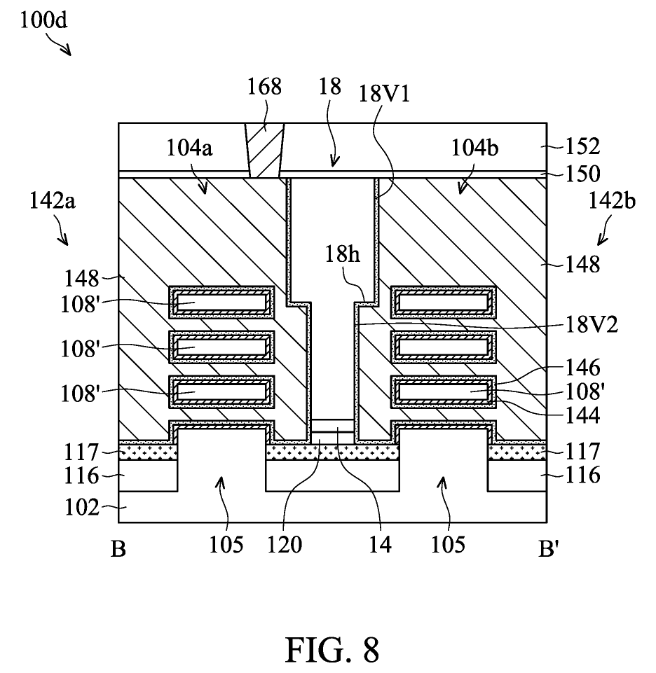

FIG. 8 illustrates a cross-sectional representation of a semiconductor structure 100d, in accordance with some embodiments. The semiconductor structure 100d of FIG. 8 includes elements that are similar to, or the same as, elements of the semiconductor structure 100a of FIG. 3N-2, the difference between FIG. 8 and FIG. 3N-2 is that the horizontal portion 18h of the dielectric wall structure 18 is lower than the topmost surface of the nanostructures 108’.

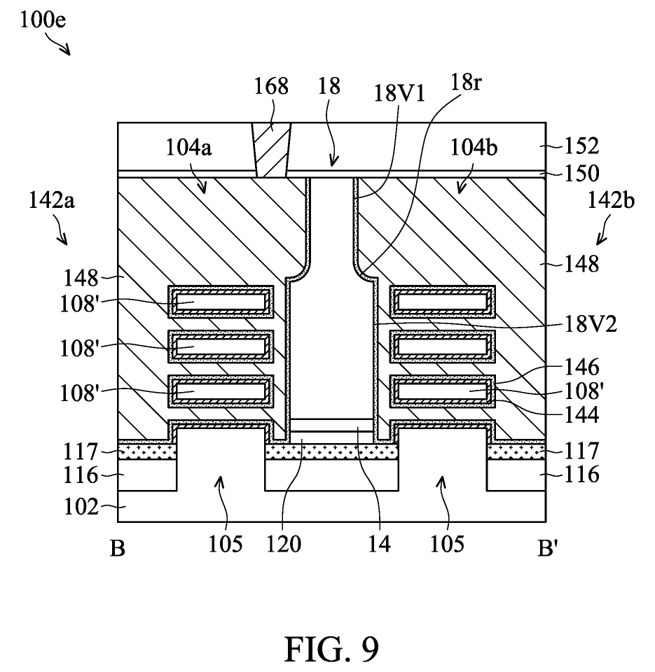

FIG. 9 illustrates a cross-sectional representation of a semiconductor structure 100e, in accordance with some embodiments. The semiconductor structure 100e of FIG. 9 includes elements that are similar to, or the same as, elements of the semiconductor structure 100a of FIG. 3N-2, the difference between FIG. 9 and FIG. 3N-2 is that a rounded portion 18r is between the top vertical portion 18V1 and the bottom vertical portion 18V2 of the dielectric wall structure 18. The rounded portion 18r has a curved surface.

The dielectric wall structure 18 of the semiconductor structure 100a to 100e has a reversed T-shaped structure, therefore the gate contact structure 168 is formed on the first gate structure 142a and is not in contact with the dielectric wall structure 18 to have more landing window. In addition, the first gate structure 142a is filled into the space between the dielectric wall structure 18 and the nanostructures 108’ to further reduce the unwanted capacitance. Therefore, the performance of the semiconductor structure 100a to 100e is improved.

It should be appreciated that the semiconductor structures 100a to 100e having the dielectric wall structure 18 with reversed-T shaped structure between the first gate structure 142a and the second gate structure 142b described above may also be applied to FinFET structures, although not shown in the figures.

It should be noted that same elements in FIGS. 1A to 9 may be designated by the same numerals and may include similar or the same materials and may be formed by similar or the same processes; therefore such redundant details are omitted in the interest of brevity. In addition, although FIGS. 1A to 9 are described in relation to the method, it will be appreciated that the structures disclosed in FIGS. 1A to 9 are not limited to the method but may stand alone as structures independent of the method. Similarly, although the methods shown in FIGS. 1A to 9 are not limited to the disclosed structures but may stand alone independent of the structures. Furthermore, the nanostructures described above may include nanowires, nanosheets, or other applicable nanostructures in accordance with some embodiments.

Also, while disclosed methods are illustrated and described below as a series of acts or events, it will be appreciated that the illustrated ordering of such acts or events may be altered in some other embodiments. For example, some acts may occur in different orders and/or concurrently with other acts or events apart from those illustrated and/or described above. In addition, not all illustrated acts may be required to implement one or more aspects or embodiments of the description above. Further, one or more of the acts depicted above may be carried out in one or more separate acts and/or phases.

Furthermore, the terms “approximately,” “substantially,” “substantial” and “about” describe above account for small variations and may be varied in different technologies and be in the deviation range understood by the skilled in the art. For example, when used in conjunction with an event or circumstance, the terms can refer to instances in which the event or circumstance occurs precisely as well as instances in which the event or circumstance occurs to a close approximation.

Embodiments for forming semiconductor structures may be provided. The semiconductor structure includes first nanostructures and second nanostructures formed over a substrate along a first direction (e.g. x-axis). A first gate structure is formed over the first nanostructures, and a second gate structure is formed over the second nanostructures. A dielectric wall structure is between the first gate structure and the second gate structure. A first S/D structure is adjacent to the first gate structure, and a second S/D structure is adjacent to the second gate structure. The dielectric wall structure extends from the gate region to the S/D region. The dielectric wall structure has a reversed T-shaped structure, therefore gate contact structure is formed on the first gate structure and is not in contact with the dielectric wall structure to have more landing window. In addition, the first gate structure is filled into the space between the dielectric wall structure and the nanostructures to further reduce capacitance. Therefore, the performance of the semiconductor structure is improved.

In some embodiments, a semiconductor structure is provided. The semiconductor structure includes a plurality of first nanostructures formed over a substrate along a first direction, and a plurality of second nanostructures formed adjacent to the first nanostructures. The semiconductor structure includes a first gate structure formed on the first nanostructures along a second direction, and the first gate structure includes a first gate dielectric layer. The semiconductor structure includes a second gate structure formed on the second nanostructures. The semiconductor structure includes a dielectric wall structure between the first gate structure and the second gate structure along the first direction. The dielectric wall structure has a top portion and a bottom portion, and the bottom portion is wider than the top portion. The semiconductor structure includes a liner layer below the dielectric wall structure, and the first gate dielectric layer is formed on a sidewall surface of the liner layer and a sidewall surface of the dielectric wall structure.

In some embodiments, a semiconductor structure is provided. The semiconductor structure includes a plurality of first nanostructures formed over a substrate, and a plurality of second nanostructures formed adjacent to the first nanostructures. The semiconductor structure includes a first gate structure formed on the first nanostructures, and a second gate structure formed on the second nanostructures. A dielectric wall structure between the first gate structure and the second gate structure. The dielectric wall structure has a top portion and a bottom portion, a first distance is between a sidewall surface of the top portion and a sidewall surface of a topmost first nanostructure, and a second distance is between a sidewall surface of the bottom portion and the sidewall surface of the topmost first nanostructure. The first distance is greater than the second distance.

In some embodiments, a method for forming a semiconductor structure is provided. The method includes forming a first fin structure and a second fin structure over a substrate, respectively, and the first fin structure includes first semiconductor material layers and second semiconductor material layers alternately stacked, and the second fin structure includes first semiconductor material layers and second semiconductor material layers alternately stacked. The method includes forming a first dummy gate structure over the first fin structure and the second fin structure, and the first dummy gate structure includes a first dummy gate dielectric layer and a first dummy gate electrode layer. The method includes replacing the first semiconductor material layers with dummy dielectric layers, such that the dummy dielectric layers and the second semiconductor material layers are alternately stacked. The method includes removing a portion of the first dummy gate electrode layer to form an opening, and forming a liner layer in the opening. The method includes forming a dielectric wall material in the opening, and removing another portion of the first dummy gate electrode layer. The method includes removing a portion of the liner layer, and removing a portion of the first dummy gate dielectric layer and a portion of the dielectric wall material to form a dielectric wall structure. The remaining portion of the liner layer and the remaining portion of the first dummy gate dielectric layer are directly below the dielectric wall structure. The method includes removing the dummy dielectric layers to form gaps, and forming a first gate structure in the gaps.

In some embodiments, a semiconductor structure is provided. The semiconductor structure includes a plurality of first nanostructures formed over a substrate along a first direction, a plurality of second nanostructures formed adjacent to the first nanostructures. The semiconductor structure includes a first gate structure in a gate region formed on the first nanostructures along a second direction, and a first S/D structure in an S/D region adjacent to the first gate structure. The semiconductor structure includes a second gate structure formed on the second nanostructures. The semiconductor structure includes a dielectric wall structure formed along the first direction, and the dielectric wall structure has a first portion in the gate region and a second portion in the S/D region, and a bottom surface of the second portion is higher than a bottom surface of the first portion of the dielectric wall structure.

In some embodiments, a semiconductor structure is provided. The semiconductor structure includes a plurality of first nanostructures formed over a substrate, and a plurality of second nanostructures formed adjacent to the first nanostructures. The semiconductor structure includes a first gate structure formed on the first nanostructures, and the first gate structure comprises a first gate dielectric layer. The semiconductor structure includes a second gate structure formed on the second nanostructures. The semiconductor structure includes a dielectric wall structure between the first gate structure and the second gate structure, wherein a top surface of the first gate dielectric layer is higher than a topmost surface of the first nanostructures.

In some embodiments, a method for forming a semiconductor structure is provided. The method includes forming a first stack structure and a second stack structure over a substrate, and forming a dummy gate structure over the first stack structure and the second stack structure, wherein the dummy gate structure comprises a dummy gate dielectric layer and a dummy gate electrode layer. The method includes removing a portion of the dummy gate electrode layer to form an opening, wherein a portion of the dummy gate dielectric layer is exposed by the opening, and the opening has a top width greater than a bottom width. The method includes forming a dielectric wall material in the opening, and removing another portion of the dummy gate electrode layer. The method includes removing a portion of the dummy gate dielectric layer and a portion of the dielectric wall material to form a dielectric wall structure, and a remaining portion of the dummy gate dielectric layer is below the dielectric wall structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a plurality of first nanostructures formed over a substrate along a first direction;
a plurality of second nanostructures formed adjacent to the first nanostructures;
a first gate structure in a gate region formed on the first nanostructures along a second direction;
a first S/D structure in an S/D region adjacent to the first gate structure;
a second gate structure formed on the second nanostructures; and
a dielectric wall structure formed along the first direction, wherein the dielectric wall structure has a first portion in the gate region and a second portion in the S/D region, and a bottom surface of the second portion is higher than a bottom surface of the first portion of the dielectric wall structure.

2. The semiconductor structure as claimed in claim 1, wherein the bottom surface of the second portion is higher than a top surface of the first S/D structure.

3. The semiconductor structure as claimed in claim 1, further comprising:
a liner layer below the first portion of the dielectric wall structure; and
a dielectric layer below the liner layer.

4. The semiconductor structure as claimed in claim 1, further comprising:
a liner layer below the second portion of the dielectric wall structure, wherein the liner layer has U-shaped structure.

5. The semiconductor structure as claimed in claim 1, wherein the dielectric wall structure has a reversed T-shaped structure.

6. The semiconductor structure as claimed in claim 1, further comprising:
an isolation structure formed on the substrate; and
a mask layer formed on the isolation structure, wherein the mask layer is between the isolation structure and the dielectric wall structure.

7. The semiconductor structure as claimed in claim 1, wherein the first gate structure comprises a first gate dielectric layer, and the first gate dielectric layer interfaces with a sidewall surface of the first portion of the dielectric wall structure.

8. The semiconductor structure as claimed in claim 1, wherein the dielectric wall structure has a sidewall surface, and the sidewall surface has a top vertical portion, a horizontal portion, and a bottom vertical portion, the horizontal portion is between the top vertical portion and the bottom vertical portion, and the horizontal portion is higher than a topmost surface of the first nanostructures.

9. The semiconductor structure as claimed in claim 1, further comprising:
a fin spacer layer adjacent to the first S/D structure, wherein the bottom surface of the second portion is higher than a top surface of the fin spacer layer.

10. A semiconductor structure, comprising:
a plurality of first nanostructures formed over a substrate;
a plurality of second nanostructures formed adjacent to the first nanostructures;
a first gate structure formed on the first nanostructures, wherein the first gate structure comprises a first gate dielectric layer;
a second gate structure formed on the second nanostructures; and
a dielectric wall structure between the first gate structure and the second gate structure, wherein a top surface of the first gate dielectric layer is higher than a topmost surface of the first nanostructures.

11. The semiconductor structure as claimed in claim 10, further comprising:
a liner layer below the dielectric wall structure, wherein the liner layer interfaces with the first gate dielectric layer.

12. The semiconductor structure as claimed in claim 11, further comprising:
an isolation structure formed on the substrate; and
a fin base structure below the first nanostructures, wherein a top surface of the fin base structure is lower than a top surface of the liner layer.

13. The semiconductor structure as claimed in claim 12, further comprising:
a mask layer formed on the isolation structure, wherein the top surface of the fin base structure is higher than a top surface of the mask layer.

14. The semiconductor structure as claimed in claim 10, further comprising:
a first S/D structure adjacent to the first gate structure, wherein the dielectric wall structure has an extending portion which is adjacent to the first S/D structure.

15. The semiconductor structure as claimed in claim 14, further comprising:
an S/D contact structure formed over the first S/D structure, wherein a bottom surface of the S/D contact structure is lower than a bottom surface of the extending portion of the dielectric wall structure.

16. The semiconductor structure as claimed in claim 10, wherein the dielectric wall structure has a sidewall surface, and the sidewall surface has a top vertical portion, a horizontal portion, and a bottom vertical portion, the horizontal portion is between the top vertical portion and the bottom vertical portion, and the horizontal portion is lower than a topmost surface of the first nanostructures.

17. A method for forming a semiconductor structure, comprising:
forming a first stack structure and a second stack structure over a substrate;
forming a dummy gate structure over the first stack structure and the second stack structure, wherein the dummy gate structure comprises a dummy gate dielectric layer and a dummy gate electrode layer;
removing a portion of the dummy gate electrode layer to form an opening, wherein a portion of the dummy gate dielectric layer is exposed by the opening, and the opening has a top width greater than a bottom width;
forming a dielectric wall material in the opening;
removing another portion of the dummy gate electrode layer; and
removing a portion of the dummy gate dielectric layer and a portion of the dielectric wall material to form a dielectric wall structure, and a remaining portion of the dummy gate dielectric layer is below the dielectric wall structure.

18. The method for forming the semiconductor structure as claimed in claim 17, wherein the first stack structure comprises first semiconductor material layers and second semiconductor material layers alternately stacked, and the second stack structure comprises first semiconductor material layers and second semiconductor material layers alternately stacked, the method further comprising:
replacing the first semiconductor material layers with dummy dielectric layers, such that the dummy dielectric layers and the second semiconductor material layers are alternately stacked;
removing the dummy dielectric layers to form gaps; and
forming a first gate structure in the gaps.

19. The method for forming the semiconductor structure as claimed in claim 17, further comprising:
forming an isolation structure on the substrate; and
forming a mask layer on the isolation structure, wherein the mask layer is separated from the dielectric wall structure by the remaining portion of the dummy gate dielectric layer.

20. The method for forming the semiconductor structure as claimed in claim 17, further comprising:
removing a portion of the first stack structure to form a plurality of nanostructures, wherein the dielectric wall structure is separated from the nanostructures.
